(19) United States
(12) Patent Application Publication
(10) Pub. No.: US 2016/0013089 A1
(43) Pub. Date: Jan. 14, 2016

(54) SEMICONDUCTOR DEVICE PRODUCTION METHOD, SHEET-SHAPED RESIN COMPOSITION, DICING TAPE-INTEGRATED SHEET-SHAPED RESIN COMPOSITION

(71) Applicant: NITTO DENKO CORPORATION, Ibaraki-shi, Osaka (JP)

(72) Inventors: Naohide Takamoto, Ibaraki-shi (JP); Kosuke Morita, Ibaraki-shi (JP); Akihiro Fukui, Ibaraki-shi (JP); Hiroyuki Hanazono, Ibaraki-shi (JP); Akira Suzuki, Ibaraki-shi (JP)

(21) Appl. No.: 14/772,724

(22) PCT Filed: Feb. 28, 2014
(86) PCT No.: PCT/JP2014/055131

§ 371 Date: Sep. 3, 2015

(30) Foreign Application Priority Data
Mar. 4, 2013 (JP) 2013-042123
Mar. 4, 2013 (JP) 2013-042128
Mar. 4, 2013 (JP) 2013-042151

(51) Int. Cl. H01L 21/683; B32B 27/08; C08J 5/18; H01L 21/78

(52) U.S. Cl. CPC H01L 21/6836; H01L 21/78; B32B 27/08; C08J 5/18; B32B 2270/00; B32B 2457/14; B32B 2405/00; C08J 2333/12; C08J 2333/08; C08J 2463/00; C08J 2461/06

(57) ABSTRACT

A production method for a semiconductor device is provided whereby, when peeling a support body from an attached wafer, melting of a sheet-shaped resin composition pasted to the other surface of the wafer can be suppressed. The method comprises: preparing a support body-attached wafer, said support body-attached wafer having the support body bonded, via a temporary fixing layer, to one surface of the wafer having a through electrode formed therein; preparing a dicing tape-integrated sheet-shaped resin composition having a sheet-shaped resin composition having an external shape smaller than the other surface of the wafer formed upon a dicing tape; pasting the other surface of the support body-attached wafer to the sheet-shaped resin composition in the dicing tape-integrated sheet-shaped resin composition; and melting the temporary fixing layer by a solvent and peeling the support body away from the wafer.

### TECHNICAL FIELD

The present invention relates to a semiconductor device production method, a sheet-shaped resin composition, and a dicing tape-integrated sheet-shaped resin composition.

### BACKGROUND ART

In recent years, a semiconductor production technique has been used in which thinner semiconductor chips are manufactured and laminated into a multilayer while being connected with a through-silicon via (TSV) to produce a semiconductor device. In order to realize this, steps of making a thinner wafer by grinding a non-circuit-forming surface (also referred to as a backside) of the wafer in which a semiconductor circuit is formed and of forming electrodes including the TSV on the backside (for example, refer to Patent Document 1) are necessary.

In this semiconductor production technique, the backside grinding is performed while a support is bonded to the wafer in order to make up for the insufficiency of strength caused by making the wafer thinner. When the through electrode is formed, a process at high temperature (for example, 250° C. or more) is included. Therefore, a material having heat resistance (for example, heat resistant glass) is used for the support.

On the other hand, a sheet-shaped resin composition has been conventionally known that is used in a flip-chip type semiconductor device in which a semiconductor chip is mounted by flip-chip bonding (flip-chip bonded) on a substrate, and used for sealing the interface between the semiconductor chip and the substrate (for example, refer to Patent Document 2).

FIGS. 22 to 25 are drawings for explaining one example of a conventional semiconductor device production method. As shown in FIG. 22, in the conventional semiconductor device production method, a wafer 1100 with a support, which includes a wafer 1110, a temporary fixing sheet 1130, and a support 1120 bonded to one side 1110a of the wafer 1110, on which a through electrode (not shown in the drawing) is formed, with the temporary fixing sheet 1130 interposed therebetween, is prepared first. For example, the wafer 1100 with a support can be obtained with a step of bonding the circuit forming side of the wafer having a circuit forming side and a non-circuit-forming side to the support with a temporary fixing layer interposed therebetween, a step of grinding the non-circuit-forming side of the wafer that is bonded to the support, and a step of performing processes (for example, forming the TSV, forming an electrode, and forming a metal wiring) on the grinded non-circuit-forming side of the wafer. The support is bonded to the wafer to secure the strength of the wafer when the wafer is grinded. The step of performing the processes described above includes processes at a high temperature (for example, 250° C. or more). Therefore, a material having a certain level of strength and heat resistance (for example, a heat resistant glass) is used for the support.

Next, as shown in FIG. 23, a dicing tape-integrated sheet-shaped resin composition 1140 which includes a dicing tape 1150 and a sheet-shaped resin composition 1160 formed on the dicing tape 1150 is prepared. For example, the sheet-shaped resin composition disclosed in Patent Document 2 is used as the sheet-shaped resin composition 1160.

Next, as shown in FIG. 24, the other side 1110b of the wafer 1100 with a support is pasted to the sheet-shaped resin composition 1160 of the dicing tape-integrated sheet-shaped resin composition 1140.

Next, as shown in FIG. 25, a temporary fixing layer 130 is dissolved by a solvent to peel the support 1120 from the wafer 1110.

After that, the wafer 1110 is diced together with the sheet-shaped resin composition 1160 to form a chip with the sheet-shaped resin composition (not shown in the drawing). The chip with the sheet-shaped resin composition is pasted to a mounting substrate, the electrodes of the chip and the electrodes of the mounting substrate are bonded, and the space between the chip and the mounting substrate is sealed with the sheet-shaped composition.

The chip in which the through electrode is thereby formed is mounted to the mounting substrate, and a semiconductor device can be obtained in which the space between the chip and the mounting substrate is sealed with the sheet-shaped composition.

### PRIOR ART DOCUMENTS

### Patent Documents

Patent Document 1: JP-A-2012-12573

Patent Document 2: JP-B2-4438973

### SUMMARY OF THE INVENTION

### Problems to be Solved by the Invention

In the conventional semiconductor device production method, the side surface of the sheet-shaped resin composition 1160 is exposed when performing the step of dissolution of the temporary fixing layer 130 by a solvent to peel the support 1120 from the wafer 1110. Therefore, the sheet-shaped resin composition 1160 is also dissolved by the solvent (refer to FIG. 25). Therefore, the sheet-shaped resin composition may not function as a sheet-shaped resin composition for sealing the space between the chip and the mounting substrate. In addition, the yield ratio may be decreased.

The present invention (a first part of the present invention to a third part of the present invention) has been performed in consideration of the above-described problems, and its purpose is to provide a semiconductor device production method in which the dissolution of the sheet-shaped resin composition that is pasted to the other side of the wafer with a support where the support is not attached can be suppressed when the support is peeled off from the wafer with a support in which the wafer and the support are bonded with the temporary fixing layer interposed therebetween, the sheet-shaped resin composition that is used in the semiconductor device production method, and a dicing tape-integrated sheet-shaped resin composition that is used in the semiconductor device production method.

### Means for Solving the Problems

The present inventors found that the above-described problems can be solved by adopting the following configuration, and the present invention was completed.

The first part of the present invention is a semiconductor device production method including:

a step A of preparing a wafer with a support including a wafer, a temporary fixing layer, and a support bonded to one side of the wafer, on which a through electrode is formed, with the temporary fixing layer interposed therebetween,

a step B of preparing a dicing tape-integrated sheet-shaped resin composition including a dicing tape and a sheet-shaped resin composition smaller in an outer shape than the other side of the wafer, formed on the dicing tape,

a step C of pasting the other side of the wafer with a support to the sheet-shaped resin composition of the dicing tape-integrated sheet-shaped resin composition, and

a step D of dissolving the temporary fixing layer with a solvent to peel the support from the wafer.

According to the semiconductor device production method of the first part of the present invention, after preparing a wafer with a support including a wafer, a temporary fixing layer, and a support bonded to one side of the wafer with the temporary fixing layer interposed therebetween, and a dicing tape-integrated sheet-shaped resin composition including a dicing tape and a sheet-shaped resin composition smaller in an outer shape than the other side of the wafer formed on the dicing tape, the other side of the wafer with a support is pasted to the sheet-shaped resin composition of the dicing tape-integrated sheet-shaped resin composition. Because the sheet-shaped resin composition is smaller in outer shape than the other side of the wafer, when the temporary fixing layer is dissolved by a solvent to peel the support from the wafer, the solvent does not easily flow around the sheet-shaped resin composition. As a result, dissolution of the sheet-shaped resin composition can be suppressed. For example, because the side of the sheet-shaped resin composition 1160 is exposed in the conventional method shown in FIG. 25, after the sheet-shaped resin composition 1160 is dissolved by the solvent, the solvent penetrates between the wafer 1110 and the sheet-shaped resin composition 1160. However, because the solvent does not easily flow around the sheet-shaped resin composition in the first part of the present invention, the penetration of the solvent between the wafer and the sheet-shaped resin composition is suppressed. As a result, a decrease of the yield ratio can be suppressed.

In this configuration, after the step D, the semiconductor device production method preferably includes a step E of dicing the wafer together with the sheet-shaped resin composition to obtain a chip with the sheet-shaped resin composition. As described above, dissolution of the sheet-shaped resin composition is suppressed. Therefore, the sheet-shaped resin composition of the chip with the sheet-shaped resin composition that is obtained in the step E sufficiently functions as a sheet-shaped resin composition for sealing the space between the chip and the mounting substrate.

In this configuration, after the step E, the semiconductor device production method preferably includes a step F of arranging the chip with the sheet-shaped resin composition on the mounting substrate and sealing the space between the chip and the mounting substrate with the sheet-shaped composition while bonding the electrode of the chip and the electrode of the mounting substrate. As described above, the dissolution of the sheet-shaped resin composition is suppressed. Therefore, the yield ratio of the semiconductor device that is obtained in the step F (a semiconductor device in which the space between the chip and the mounting substrate is sealed with the sheet-shaped composition) can be improved.

In this configuration, the step C is preferably performed under reduced pressure. When the step C is performed under reduced pressure, the generation of voids at the interface between the wafer and the sheet-shaped resin composition can be suppressed. As a result, the wafer and the sheet-shaped resin composition can be pasted together more suitably.

In order to solve the above-described problems, the first part of the present invention is a sheet-shaped resin composition, and is used in the semiconductor device production method described above.

Further, the first part of the present invention is a dicing tape-integrated sheet-shaped resin composition, and is used in the semiconductor device production method described above. Because the dicing tape-integrated sheet-shaped resin composition is used in this configuration, it is more excellent in the respect that a step of pasting the dicing tape and the sheet-shaped resin composition together can be omitted.

The second part of the present invention is a semiconductor device, including:

a step A2 of preparing a wafer with a support including a wafer, a temporary fixing layer, and a support bonded to one side of the wafer, on which a through electrode is formed, with the temporary fixing layer interposed therebetween,

a step B2 of preparing a dicing tape-integrated sheet-shaped resin composition having a dicing tape, a sheet-shaped resin composition that is laminated on the center of the dicing tape, and a barrier layer that is laminated on the region outside of the center of the dicing tape,

a step C2 of pasting the other side of the wafer with a support to the sheet-shaped resin composition of the dicing tape-integrated sheet-shaped resin composition, and

a step D2 of dissolving the temporary fixing layer by a solvent to peel the support from the wafer.

According to the semiconductor device production method of the second part of the present invention, a wafer with a support, including a wafer, a temporary fixing layer, and a support bonded to one side of the wafer with a temporary fixing layer interposed therebetween, is prepared. A dicing tape-integrated sheet-shaped resin composition having a dicing tape, a sheet-shaped resin composition that is laminated on the center of the dicing tape, and a barrier layer that is laminated on the region outside of the center of the dicing tape, is prepared. After that, the other side of the wafer with a support is pasted to the sheet-shaped resin composition of the dicing tape-integrated sheet-shaped resin composition. Because the barrier layer is laminated on the region outside of the center of the dicing tape, at least a portion of the side surface of the sheet-shaped resin composition that is laminated on the center of the dicing tape is covered by the barrier layer. Therefore, when the temporary fixing layer is dissolved by a solvent to peel the support from the wafer, the solvent does not easily contact the sheet-shaped resin composition. As a result, dissolution of the sheet-shaped resin composition can be suppressed.

In this configuration, the sheet-shaped resin composition is preferably smaller in outer shape than the other side of the wafer, and the step C2 is preferably a step of pasting the other side of the wafer with a support to the sheet-shaped resin composition of the dicing tape-integrated sheet-shaped resin composition in the form in which the outer peripheral part of the wafer is laminated on the barrier layer. When the sheet-shaped resin composition is smaller in outer shape than the other side of the wafer, and the step C2 is a step of pasting the other side of the wafer with a support to the sheet-shaped resin composition of the dicing tape-integrated sheet-shaped resin composition in the form in which the outer peripheral part of the wafer is laminated on the barrier layer, the sheet-shaped resin composition does not easily make contact with the solvent. As a result, the dissolution of the sheet-shaped resin composition can be further suppressed.

In this configuration, after the step D2, the semiconductor device production method preferably includes a step E2 of dicing the wafer together with the sheet-shaped resin composition to obtain a chip with the sheet-shaped resin composition. As described above, dissolution of the sheet-shaped resin composition is suppressed. Therefore, the sheet-shaped resin composition of the chip with the sheet-shaped resin composition that is obtained in the step E2 sufficiently functions as a sheet-shaped resin composition for sealing the space between the chip and the mounting substrate.

In this configuration, after the step E2, the semiconductor device production method preferably includes a step F2 of arranging the chip with the sheet-shaped resin composition on the mounting substrate and sealing the space between the chip and the mounting substrate with the sheet-shaped composition while bonding the electrode of the chip and the electrode of the mounting substrate. As described above, the dissolution of the sheet-shaped resin composition is suppressed. Therefore, the yield ratio of the semiconductor device that is obtained in the step F2 (a semiconductor device in which the space between the chip and the mounting substrate is sealed with the sheet-shaped composition) can be improved.

In this configuration, the step C2 is preferably performed under reduced pressure. When the step C2 is performed under reduced pressure, the generation of voids at the interface between the wafer and the sheet-shaped resin composition can be suppressed. As a result, the wafer and the sheet-shaped resin composition can be pasted together more suitably.

In order to solve the above-described problems, the second part of the present invention is a sheet-shaped resin composition, and is used in the semiconductor device production method described above.

Further, in order to solve the above-described problems, the second part of the present invention is a dicing tape-integrated sheet-shaped resin composition; having:

a dicing tape,

a sheet-shaped resin composition for underfill that is laminated on the center of the dicing tape, and

a barrier layer that is laminated on the region outside of the center of the dicing tape.

The third part of the present invention is a semiconductor device, including:

a step A3 of preparing a wafer with a support including a wafer, a temporary fixing layer, and a support bonded to one side of the wafer, on which a through electrode is formed, with the temporary fixing layer interposed therebetween,

a step B3 of preparing a dicing tape-integrated sheet-shaped resin composition including a dicing tape and a sheet-shaped resin composition formed on the dicing tape,

a step C3 of pasting the other side of the wafer with a support to the sheet-shaped resin composition of the dicing tape-integrated sheet-shaped resin composition,

a step D3 of applying an adhesive to the portion where the sheet-shaped resin composition is exposed after the step C3, and

a step E3 of dissolving the temporary fixing layer by a solvent to peel the support from the wafer.

According to the semiconductor device production method of the third part of the present invention, after preparing a wafer with a support including a wafer, a temporary fixing layer, and a support bonded to one side of the wafer with the temporary fixing layer interposed therebetween, and a dicing tape-integrated sheet-shaped resin composition including a dicing tape and a sheet-shaped resin composition formed on the dicing tape, the other side of the wafer with a support is pasted to the sheet-shaped resin composition of the dicing tape-integrated sheet-shaped resin composition. After that, an adhesive is applied on the portion where the sheet-shaped resin composition is exposed. When an adhesive is applied on the portion where the sheet-shaped resin composition is exposed, the solvent does not easily make contact with the sheet-shaped resin composition when dissolving the temporary fixing layer to peel the support from the wafer. As a result, the dissolution of the sheet-shaped resin composition can be suppressed.

In this configuration, after the step E3, the semiconductor device production method preferably includes a step F3 of dicing the wafer together with the sheet-shaped resin composition to obtain a chip with the sheet-shaped resin composition. As described above, dissolution of the sheet-shaped resin composition is suppressed. Therefore, the sheet-shaped resin composition of the chip with the sheet-shaped resin composition that is obtained in the step F3 sufficiently functions as a sheet-shaped resin composition for sealing the space between the chip and the mounting substrate.

In this configuration, after the step F3, the semiconductor device production method preferably includes a step G3 of arranging the chip with the sheet-shaped resin composition on the mounting substrate and sealing the space between the chip and the mounting substrate with the sheet-shaped composition while bonding the electrode of the chip and the electrode of the mounting substrate. As described above, the dissolution of the sheet-shaped resin composition is suppressed. Therefore, the yield ratio of the semiconductor device that is obtained in the step G3 (a semiconductor device in which the space between the chip and the mounting substrate is sealed with the sheet-shaped composition) can be improved.

In this configuration, the step C3 is preferably performed under reduced pressure. When the step C3 is performed under reduced pressure, the generation of voids at the interface between the wafer and the sheet-shaped resin composition can be suppressed. As a result, the wafer and the sheet-shaped resin composition can be pasted together more suitably.

In order to solve the above-described problems, the third part of the present invention is a sheet-shaped resin composition, and is used in the semiconductor device production method described above.

Further, the third part of the present invention is a dicing tape-integrated sheet-shaped resin composition, and is used in the semiconductor device production method described above. Because the dicing tape-integrated sheet-shaped resin composition is used in this configuration, it is more excellent in the respect that a step of pasting the dicing tape and the sheet-shaped resin composition together can be omitted.

### Effect of the Invention

According to the present invention (the first part of the present invention to the third part of the present invention), dissolution of the sheet-shaped resin composition that is pasted to the other side of the wafer with a support when the support is peeled off from the wafer with a support, in which the wafer and the support are bonded together with the temporary fixing layer interposed therebetween, can be suppressed.

### BRIEF DESCRIPTION OF THE DRAWINGS

FIG. 1 is a schematic cross-sectional drawing for explaining the semiconductor production method according to one embodiment of the first part of the invention.

FIG. 2 is a schematic cross-sectional drawing for explaining the semiconductor production method according to one embodiment of the first part of the invention.

FIG. 3 is a schematic cross-sectional drawing for explaining the semiconductor production method according to one embodiment of the first part of the invention.

FIG. 4 is a schematic cross-sectional drawing for explaining the semiconductor production method according to one embodiment of the first part of the invention.

FIG. 5 is a schematic cross-sectional drawing for explaining the semiconductor production method according to one embodiment of the first part of the invention.

FIG. 6 is a schematic cross-sectional drawing for explaining the semiconductor production method according to one embodiment of the first part of the invention.

FIG. 7 is a schematic cross-sectional drawing for explaining the semiconductor production method according to another embodiment of the first part of the invention.

FIG. 8 is a schematic cross-sectional drawing for explaining the semiconductor production method according to another embodiment of the first part of the invention.

FIG. 9 is a schematic cross-sectional drawing for explaining the semiconductor production method according to one embodiment of the second part of the invention.

FIG. 10 is a schematic cross-sectional drawing for explaining the semiconductor production method according to one embodiment of the second part of the invention.

FIG. 11 is a schematic cross-sectional drawing for explaining the semiconductor production method according to one embodiment of the second part of the invention.

FIG. 12 is a schematic cross-sectional drawing for explaining the semiconductor production method according to one embodiment of the second part of the invention.

FIG. 13 is a schematic cross-sectional drawing for explaining the semiconductor production method according to one embodiment of the second part of the invention.

FIG. 14 is a schematic cross-sectional drawing for explaining the semiconductor production method according to one embodiment of the second part of the invention.

FIG. 15 is a schematic cross-sectional drawing for explaining the semiconductor production method according to one embodiment of the third part of the invention.

FIG. 16 is a schematic cross-sectional drawing for explaining the semiconductor production method according to one embodiment of the third part of the invention.

FIG. 17 is a schematic cross-sectional drawing for explaining the semiconductor production method according to one embodiment of the third part of the invention.

FIG. 18 is a schematic cross-sectional drawing for explaining the semiconductor production method according to one embodiment of the third part of the invention.

FIG. 19 is a schematic cross-sectional drawing for explaining the semiconductor production method according to one embodiment of the third part of the invention.

FIG. 20 is a schematic cross-sectional drawing for explaining the semiconductor production method according to one embodiment of the third part of the invention.

FIG. 21 is a schematic cross-sectional drawing for explaining the semiconductor production method according to one embodiment of the third part of the invention.

FIG. 22 is a schematic cross-sectional drawing for explaining one example of the conventional semiconductor device production method.

FIG. 23 is a schematic cross-sectional drawing for explaining one example of the conventional semiconductor device production method.

FIG. 24 is a schematic cross-sectional drawing for explaining one example of the conventional semiconductor device production method.

FIG. 25 is a schematic cross-sectional drawing for explaining one example of the conventional semiconductor device production method.

### MODE FOR CARRYING OUT THE INVENTION

### First Part of the Present Invention

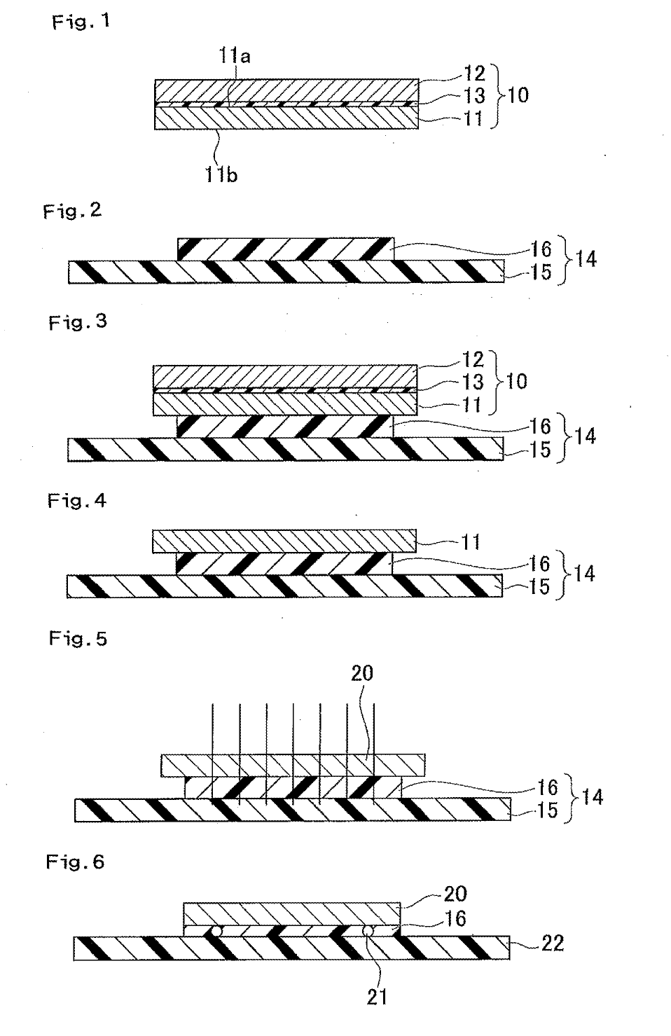

Below, the embodiment of the first part of the present invention is explained with reference to the drawings. FIGS. 1 to 6 are schematic cross-sectional drawings for explaining the semiconductor device production method according to one embodiment of the first part of the present invention.

The semiconductor device production method according to the present embodiment includes at least a step A of preparing a wafer with a support including a wafer, a temporary fixing layer, and a support bonded to one side of the wafer, on which a through electrode is formed, with the temporary fixing layer interposed therebetween (a wafer with a support preparing step), a step B of preparing a dicing tape-integrated sheet-shaped resin composition including a dicing tape and a sheet-shaped resin composition smaller in outer shape than the other side of the wafer, formed on the dicing tape (a dicing tape-integrated sheet-shaped resin composition preparing step), a step C of pasting the other side of the wafer with a support to the sheet-shaped resin composition of the dicing tape-integrated sheet-shaped resin composition (a pasting step), and a step D of dissolving the temporary fixing layer with a solvent to peel the support from the wafer (a support peeling step).

[Wafer with a Support Preparing Step]

In the step of preparing a wafer with a support (Step A), first, a wafer 10 with a support, including a wafer 11, a temporary fixing layer 13, and a support 12 bonded to one side 11a of the wafer 11, on which a through electrode (not shown in the drawing) is formed, with the temporary fixing layer 13 interposed therebetween (refer to FIG. 1), is prepared. For example, the wafer 10 with a support can be obtained with a step of bonding the circuit-forming side of a wafer having a circuit-forming side and a non-circuit-forming side (backside) to the support 12 with a temporary fixing layer 13 interposed therebetween (a support bonding step), a step of grinding the non-circuit-forming side of the wafer that is bonded to the support 12 (a wafer backside grinding step), and a step of performing processes (for example, forming the TSV (through electrode), forming an electrode, and forming a metal wiring) on the grinded non-circuit-forming side of the wafer (a non-circuit-forming side processing step). More specifically, examples of the step of performing processes on the non-circuit-forming side of the wafer are conventionally known processes for forming an electrode, such as metal sputtering, wet etching for etching the metal sputtering layer, pattern formation by applying, exposing, and developing resist to produce a mask for forming the metal wiring, peeling of the resist, dry etching, formation of metal plating, silicon etching for forming the TSV, formation of an oxide film on the surface of silicon, etc. The support 12 is bonded to the wafer 11 to secure the strength of the wafer when the wafer is grinded. The step of performing the processes described above includes processes at high temperature (for example, 250° C. or more). Therefore, a material having a certain level of strength and heat resistance (for example, a heat resistant glass) is used for the support 12.

(Support)

A material having a certain level of strength and heat resistance can be used for the support 12. Examples of the support 12 include heat resistant glass, heat resistant engineering plastic, and a wafer (for example, the wafer 11).

(Wafer)

Examples of the wafer 11 include a silicon wafer, a germanium wafer, a gallium-arsenic wafer, a gallium-phosphorus wafer, and a gallium-arsenic-aluminum wafer.

(Temporary Fixing Layer)

The adhesive composition of the temporary fixing layer 13 is not especially limited as long as the adhesive composition which is selected does not peel from the support 11 and the wafer 12 when performing the step of grinding the backside of the wafer and the step of performing processes on the non-circuit-forming side, and is dissolvable with a solvent to peel the support 11 from the wafer 12 in the step D (the support peeling step). The formation material for forming the temporary fixing layer 13 is not especially limited. However, examples include a polyimide resin, a silicone resin, an aliphatic olefin resin, a hydrogenated styrene thermoplastic elastomer, and an acrylic resin.

The polyimide resin can generally be obtained by imidization (dehydration condensation) of polyamic acid which is a precursor of the polyimide resin. Examples of the method of imidizing polyamic acid include conventionally known heating imidization, azeotropic dehydration, and chemical imidization. Among these, the heating imidization is preferable. When the heating imidization is adopted, the heating treatment is preferably performed under an inert atmosphere such as a nitrogen atmosphere or a vacuum to prevent deterioration of the polyimide resin by oxidation.

The polyamic acid can be obtained by preparing acid anhydride and diamine in a solvent that is appropriately selected essentially in equi-molar ratio and causing them to react.

The polyimide resin is not especially limited. However, a polyimide resin having a constituting unit derived from diamine having an ether structure can be used. The diamine having an ether structure is not especially limited as long as the diamine has an ether structure and is a compound with at least two ends having an amine structure. Among the diamine having the ether structure, diamine having a glycol skeleton is preferable.

Examples of the diamine having a glycol skeleton are diamine having a polypropylene glycol structure and having one amino group in each of the ends, diamine having a polyethylene glycol structure and having one amino group in each of the ends, diamine having a polytetramethylene glycol structure and having one amino group in each of the ends, and diamine having a plurality of these glycol structures and having one amino in each of the ends.

The molecular weight of the diamine having an ether structure is preferably in a range of 100 to 5,000, and more preferably 150 to 4,800. When the molecular weight of the diamine having an ether structure is in a range of 100 to 5,000, the temporary fixing layer 13 having large adhering strength at low temperature and exhibiting peelability at high temperature can be easily obtained.

In the formation of the polyimide resin, other types of diamine having no ether structure may be used together besides diamine having an ether structure. Examples of the other types of diamine having no ether structure are aliphatic diamine and aromatic diamine. When the other types of diamine having no ether structure are used together, the adhesion with the adherend can be controlled. The mixing ratio of diamine having an ether structure and diamine having no ether structure in molar ratio is preferably 100:0 to 20:80, and more preferably 99:1 to 30:70.

Examples of the aliphatic diamine include ethylene diamine, hexamethylene diamine, 1,8-diaminooctane, 1,10-diaminodecane, 1,12-diaminododecane, 4,9-dioxa-1,12-diaminododecane, and 1,3-bis(3-aminopropyl)-1,1,3,3-tetramethyldisiloxane(α,ω-bisamin opropyltetramethyldisiloxane). The molecular weight of the aliphatic diamine is normally 50 to 1,000,000, and preferably 100 to 30,000.

Examples of the aromatic diamine include 4,4′-diaminodiphenylether, 3,4′-diaminodiphenylether, 3,3′-diaminodiphenylether, m-phenylenediamine, p-phenylenediamine, 4,4′-diaminodiphenylpropane, 3,3′-diaminodiphenylmethane, 4,4′-diaminodiphenylsulfide, 3,3′-diaminodiphenylsulfide, 4,4′-diaminodiphenylsulfone, 3,3′-diaminodiphenylsulfone, 1,4-bis(4-aminophenoxy)benzene, 1,3-bis(4-aminophenoxy)benzene, 1,3-bis(3-aminophenoxy)benzene, 1,3-bis(4-aminophenoxy)-2,2-dimethylpropane, and 4,4′-diaminobenzophenone. The molecular weight of the aromatic diamine is normally 50 to 1,000, and preferably 100 to 500. In the present description, the molecular weight is measured with GPC (Gel Permeation Chromatography) and the value is expressed in terms of polystyrene (weight average molecular weight).

Examples of the acid anhydride include 3,3′,4,4′-biphenyltetracarboxylic dianhydride, 2,2′,3,3′-biphenyltetracarboxylic dianhydride, 3,3′,4,4′-benzophenonetetracarboxylic dianhydride, 2,2′,3,3′-benzophenonetetracarboxylic dianhydride, 4,4′-oxydiphthalic dianhydride, 2,2-bis(2,3-dicarboxyphenyl)hexafluoropropane dianhydride, 2,2-bis(3,4-dicarboxyphenyl)hexafluoropropane dianhydride (6FDA), bis(2,3-dicarboxyphenyl)methane dianhydride, bis(3,4-dicarboxyphenyl)methane dianhydride, bis(2,3-dicarboxyphenyl)sulfone dianhydride, bis(3,4-dicarboxyphenyl)sulfone dianhydride, pyromellitic dianhydride, and ethyleneglycol bistrimellitic dianhydride. These may be used either alone or in a combination of two or more types.

Examples of the solvent that is used in the reaction of the acid anhydride and the diamine include N,N-dimethylacetamide, N-methyl-2-pyrrolidone, N,N-dimethylformamide, and cyclopentanone. These may be used either alone or in a combination of two or more types. A nonpolar solvent such as toluene and xylene may be appropriately mixed to adjust the solubility of the raw materials and the resins.

When the polyimide resin having a constituting unit derived from diamine having an ether structure is used for the temporary fixing layer 13, the weight reduction percentage of the temporary fixing layer 13 after the temporary fixing layer 13 is soaked in N-methyl-2-pyrrolidone (NMP) at 50° C. for 60 seconds and dried at 150° C. for 30 minutes is preferably 1.0% by weight or more, more preferably 1.2% by weight or more, and further preferably 1.3% by weight or more. The larger the weight reduction percentage is, the more preferable it is. For example, the weight reduction percentage is 50% by weight or less or 30% by weight or less. When the weight reduction percentage of the temporary fixing layer 13 after the temporary fixing layer 13 is soaked in N-methyl-2-pyrrolidone (NMP) at 50° C. for 60 seconds and dried at 150° C. for 30 minutes is 1.0% by weight or more, the temporary fixing layer 13 dissolves into N-methyl-2-pyrrolidone, and the weight is considered to have been reduced sufficiently. As a result, the temporary fixing layer 13 can be easily peeled off by N-methyl-2-pyrrolidone. The weight reduction percentage of the temporary fixing layer 13 can be controlled by the solubility of the raw materials to NMP. That is, the higher the solubility of the selected raw materials to NMP is, the higher the solubility becomes of the temporary fixing layer 13 that is obtained by using the raw materials to NMP.

Examples of the silicone resin include a peroxide cross-linked silicone pressure-sensitive adhesive, an addition reaction-type silicone pressure-sensitive adhesive, a dehydrogenation reaction-type silicone pressure-sensitive adhesive, and a moisture curable silicone pressure-sensitive adhesive. These silicone resins may be used either alone or in a combination of two or more types. These silicone resins are superior in having high heat resistance. Among these silicone resins, the addition reaction-type silicone resin is preferable because such resin has less impurities.

When the silicon resin is used for the temporary fixing layer 13, the temporary fixing layer 13 may contain other additives as necessary. Examples of the other additives include a flame retardant, a silane coupling agent, and an ion trapping agent. Examples of the flame retardant include antimony trioxide, antimony pentoxide, and a brominated epoxy resin. Examples of the silane coupling agent include β-(3,4-epoxycyclohexyl)ethyltrimethoxysilane, γ-glycidoxypropyltrimethoxysilane, and γ-glycidoxypropylmethyldiethoxysilane. Examples of the ion trapping agent include hydrotalcites and bismuth hydroxide. These additives may be used either alone or in a combination of two or more types.

The acrylic resin is not especially limited. However, an example includes a polymer (an acrylic copolymer) having one type or two types or more of acrylate or methacrylate having a straight chain alkyl group or a branched alkyl group having 30 carbons or less, especially 4 to 18 carbons as a component. Examples of the alkyl group include a methyl group, an ethyl group, a propyl group, an isopropyl group, an n-butyl group, a t-butyl group, an isobutyl group, an amyl group, an isoamyl group, a hexyl group, a heptyl group, a cyclohexyl group, a 2-ethylhexyl group, an octyl group, an isooctyl group, a nonyl group, an isononyl group, a decyl group, an isodecyl group, an undecyl group, a lauryl group, a tridecyl group, a tetradecyl group, a stearyl group, an octadecyl group, and a dodecyl group.

Other monomers that form the polymer are not especially limited. However, examples include a monomer containing a carboxyl group such as acrylic acid, methacrylic acid, carboxyethylacrylate, carboxypentylacrylate, itaconic acid, maleic acid, fumaric acid, and crotonic acid; an acid anhydride monomer such as maleic anhydride and itaconic anhydride; a monomer containing a hydroxyl group such as 2-hydroxyethyl(meth)acrylate, 2-hydroxypropyl(meth)acrylate, 4-hydroxybutyl(meth)acrylate, 6-hydroxyhexyl(meth)acrylate, 8-hydroxoctyl(meth)acrylate, 10-hydroxydecyl(meth)acrylate, 12-hydroxylauryl(meth)acrylate, and (4-hydroxymethylcyclohexyl)-methylacrylate; a monomer containing sulfonic acid group such as styrenesulfonic acid, allylsulfonic acid, 2-(meth)acrylamide-2-methylpropanesulfonic acid, (meth)acrylamidepropane sulfonic acid, sulfopropyl(meth)acrylate, and (meth)acryloyloxynaphthalenesulfonic acid; and a monomer containing a phosphate group such as 2-hydroxyehylacryloylphosphate.

The temporary fixing layer 13 can be produced as follows for example. First, a resin composition solution for forming the temporary fixing layer (a solution containing the polyamic acid when the temporary fixing layer 13 is formed with a polyimide resin) is produced. Next, the solution is applied on a base to form a coating film having a prescribed thickness, and the coating film is dried under a prescribed condition. Examples of the base include SUS304; 6-4 alloy; a metal foil such as an aluminum foil, a copper foil, and a Ni foil; polyethyleneterephthalate (PET); polyethylene; polypropylene; and a plastic film and paper in which the surface is coated with a release agent such as a fluorine release agent and a long chain alkylacrylate release agent. The application method is not especially limited. However, examples include roll coating, screen coating, gravure coating, and spin coating. For the drying conditions, for example, the drying temperature is 50° C. to 150° C. and the drying time is 3 minutes to 30 minutes. The temporary fixing layer 13 according to the present embodiment can thus be obtained.

The wafer 10 with a support in which the wafer 11 and the support 12 are bonded with the temporary fixing layer 13 interposed therebetween can be produced by transferring the temporary fixing layer 13 to the support 12 and pasting the wafer 11. Or the wafer 10 with a support can be produced by transferring the temporary fixing layer 13 to the wafer 11 and pasting the support 12. Further, the wafer 10 with a support may be produced by directly applying the resin composition solution for forming the temporary fixing layer to the support 12 to form a coating film, drying the coating film under a prescribed condition to form the temporary fixing layer 13, and pasting the wafer 11. Or the wafer 10 with a support may be produced by directly applying the resin composition solution for forming the temporary fixing layer to the wafer 11 to form a coating film, drying the coating film under a prescribed condition to form the temporary fixing layer 13, and pasting the support 12.

[Dicing Tape-Integrated Sheet-Shaped Resin Composition Preparing Step]

Next, in the dicing tape-integrated sheet-shaped resin composition preparing step (Step B), a sheet-shaped resin composition 14 including a dicing tape 15 and a sheet-shaped resin composition 16 smaller in outer shape than the other side 11b of the wafer 11 formed on the dicing tape 15 (refer to FIG. 2) is prepared. The dicing tape-integrated sheet-shaped resin composition 14 may be prepared such that the dicing tape 15 and the sheet-shaped resin composition 16 are pasted together in advance, or may be prepared such that the dicing tape 15 and the sheet-shaped resin composition 16 are separately prepared and these are pasted together. The shape of the sheet-shaped resin composition 16 is not especially limited as long as the sheet-shaped resin composition 16 is smaller in outer shape than the other side 11b of the wafer 11, and may be circular, rectangular, etc. The sheet-shaped resin composition 16 smaller in outer shape than the other side 11b of the wafer 11 means the sheet-shaped resin composition 16 having a shape in which the outer peripheral part of the other side 11b of the wafer 11 is not coated with the sheet-shaped resin composition 16 when they are pasted together. An example of the shape of the sheet-shaped resin composition 16 is a round shape smaller in diameter than the wafer 11 (for example, the diameter of the sheet-shaped resin composition 16 is 280 mm) when the wafer 11 has a round shape (for example, the diameter of the wafer 11 is 290 mm). In this case, the wafer 11 and the sheet-shaped resin composition 16 are preferably laminated so that the centers are aligned.

(Dicing Tape)

The dicing tape 15 is configured with a pressure-sensitive adhesive layer formed on a base. The base can be used as abase support of the pressure-sensitive adhesive layer, etc. Examples of the base include thin sheets of a paper base such as paper; a fiber base such as cloth, nonwoven cloth, felt, and net; a metal base such as a metal foil and a metal plate; a plastic base such as a plastic film; a rubber base such as a rubber sheet; a foaming body such as a foaming sheet; and a laminate of these (for example, a laminate of the plastic base and other bases and a laminate of the plastic films). The plastic base can be suitably used as the base of the first part of the present invention. Examples of the material for the plastic base include an olefin resin such as polyethylene (PE), polypropylene (PP), and an ethylene-propylene copolymer; a copolymer having ethylene as a monomer component such as an ethylene-vinylacetate copolymer (EVA), an ionomer resin, an ethylene-(meth)acrylic acid copolymer, and an ethylene-(meth)acrylate (random, alternating) copolymer; polyester such as polyethyleneterephthalate (PET), polyethylenenaphthalate (PEN), and polybutyleneterephthalate (PBT); an acrylic resin; polyvinylchloride (PVC); polyurethane; polycarbonate; polyphenylenesulfide (PPS); an amide resin such as polyamide (nylon) and fully aromatic polyamide (aramid); polyetheretherketone (PEEK); polyimide; ABS (an acrylonitrile-butadiene-styrene copolymer); a cellulose resin; a silicone resin; and a fluorine resin.

An example of the material of the base is a polymer such as a cross-linked body of the above-described resin. The plastic film used may be non-stretched or may be uniaxially stretched or biaxially stretched according to necessity. With the resin sheet in which a heat shrinking property is given by the stretching treatment, etc., the contact area of the pressure-sensitive adhesive layer and the sheet-shaped resin composition 16 is decreased by thermally shrinking the base after dicing to make the collection of semiconductor elements easy.

In order to improve the tackiness, the retention, etc. with the adjacent layer, the surface of the base can be treated with a traditional surface treatment, for example, a chemical treatment or a physical treatment such as a chromic acid treatment, ozone exposure, flame exposure, high pressure electric shock exposure, or an ionized radiation treatment; and a coating treatment with a primer (for example, a pressure-sensitive adhesive substance described later).

The same types or different types of the base can be appropriately selected and used, and several types can be blended and used for the base as necessary. In order to give the antistatic performance to the base, a vapor deposition layer of a conductive substance having a thickness of about 30 Å to 500 Å and consisting of a metal or an alloy, an oxide thereof, or the like can be provided on the base. The base may be a single layer or a multilayer of two types or more.

The thickness of the base (a total thickness when the base is a laminate) is not especially limited. However, the thickness can be appropriately selected depending on the strength, the flexibility, the purpose of use, etc. For example, the thickness of the base is generally 1,000 μm or less (for example, 1 μm to 1,000 μm), preferably 10 μm to 500 μm, more preferably 20 μm to 300 μm, and especially preferably 30 μm to 200 μm. However, the thickness is not limited to these ranges.

The base may contain various types of additives (a coloring agent, a filler, a plasticizer, an antiaging agent, an antioxidant, a surfactant, a flame retardant, etc.) within a range wherein the effect, etc., of the first part of the present invention is not lost.

The pressure-sensitive adhesive layer is formed with the pressure-sensitive adhesive, and has the adhereability. The pressure-sensitive adhesive is not especially limited, and can be appropriately selected from the known pressure-sensitive adhesives. Specifically, a pressure-sensitive adhesive having the characteristics described above can be selected from known pressure-sensitive adhesives such as an acrylic pressure-sensitive adhesive, a rubber pressure-sensitive adhesive, a vinylalkylether pressure-sensitive adhesive, a silicone pressure-sensitive adhesive, a polyester pressure-sensitive adhesive, a polyamide pressure-sensitive adhesive, a urethane pressure-sensitive adhesive, a fluorine pressure-sensitive adhesive, a styrene-diene block copolymer pressure-sensitive adhesive, and a pressure-sensitive adhesive with improved creep properties in which a thermally melting resin having a melting point of 200° C. or less is added to the above pressure-sensitive adhesive (for example, refer to JP-A-56-61468, JP-A-61-174857, JP-A-63-17981, JP-A-56-13040, etc.). In addition, a radiation curable pressure-sensitive adhesive (or an energy ray curable pressure-sensitive adhesive) or a thermoexpandable pressure-sensitive adhesive may be used. These pressure-sensitive adhesives may be used either alone or in a combination of two or more types.

The acrylic pressure-sensitive adhesive and the rubber pressure-sensitive adhesive can be suitably used as the pressure-sensitive adhesive, and the acrylic pressure-sensitive adhesive is especially suitable. An example of the acrylic pressure-sensitive adhesive includes an acrylic pressure-sensitive adhesive having an acrylic polymer (a single polymer or a copolymer) as the base polymer, in which one type or two or more types of alkyl(meth)acrylate are used as the monomer component.

Examples of the alkyl(meth)acrylate in the acrylic pressure-sensitive adhesive include methyl(meth)acrylate, ethyl(meth)acrylate, propyl(meth)acrylate, isopropyl(meth)acrylate, butyl(meth)acrylate, isobutyl(meth)acrylate, s-butyl(meth)acrylate, t-butyl(meth)acrylate, pentyl(meth)acrylate, hexyl(meth)acrylate, heptyl(meth)acrylate, octyl(meth)acrylate, 2-ethylhexyl(meth)acrylate, isooctyl(meth)acrylate, nonyl(meth)acrylate, isononyl(meth)acrylate, decyl(meth)acrylate, isodecyl(meth)acrylate, undecyl(meth)acrylate, dodecyl(meth)acrylate, tridecyl(meth)acrylate, tetradecyl(meth)acrylate, pentadecyl(meth)acrylate, hexadecyl(meth)acrylate, heptadecyl(meth)acrylate, octadecyl(meth)acrylate, nonadecyl(meth)acrylate, and eicosyl(meth)acrylate. The alkyl(meth)acrylate preferably has an alkyl group having 4 to 18 carbon atoms. The alkyl group of the alkyl(meth)acrylate may be either of a straight chain or a branched chain.

The acrylic polymer may contain a unit corresponding to other monomer components (copolymerizable monomer component) that are copolymerizable with the alkyl(meth)acrylate as necessary for the purpose of modifying the cohesion, the heat resistance, the cross-linking property, etc. Examples of the copolymerizable monomer components include a monomer containing a carboxyl group such as (meth)acrylic acid (acrylic acid, methacrylic acid), carboxyethylacrylate, carboxypentylacrylate, itaconic acid, maleic acid, fumaric acid, and crotonic acid; a monomer containing an acid anhydride such as maleic anhydride and itaconic anhydride; a monomer containing a hydroxyl group such as hydroxyethyl(meth)acrylate, hydroxypropyl(meth)acrylate, hydroxybutyl(meth)acrylate, hydroxyhexyl(meth)acrylate, hydroxyoctyl(meth)acrylate, hydroxydecyl(meth)acrylate, hydroxylauryl(meth)acrylate, and (4-hydroxymethylcyclohexyl)methylmethacrylate; a monomer containing a sulfonic acid group such as styrenesulfonic acid, allylsulfonic acid, 2-(meth)acrylamide-2-methylpropanesulfonic acid, (meth)acrylamidepropanesulfonic acid, sulfopropyl(meth)acrylate, and (meth)acryloyloxynaphthalene sulfonic acid; a monomer containing a phosphoric acid group such as 2-hydroxyethylacryloylphosphate; an (N-substituted) amide monomer such as (meth)acrylamide, N,N-dimethyl(meth)acrylamide, N-butyl(meth)acrylamide, N-methylol(meth)acrylamide, and N-methylolpropane(meth)acrylamide; an aminoalkyl(meth)acrylate monomer such as aminoethyl(meth)acrylate, N,N-dimethylaminoethyl(meth)acrylate, and t-butylaminoethyl(meth)acrylate; an alkoxyalkyl(meth)acrylate monomer such as methoxyethyl(meth)acrylate and ethoxyethyl(meth)acrylate; a cyanoacrylate monomer such as acrylonitrile and methacrylonitrile; an acrylic monomer containing an epoxy group such as glycidyl(meth)acrylate; a styrene monomer such as styrene and α-methylstyrene; a vinylester monomer such as vinylacetate and vinylpropionate; an olefin monomer such as isoprene, butadiene, and isobutylene; a vinylether monomer such as vinylether; a monomer containing nitrogen such as N-vinylpyrrolidone, methylvinylpyrrolidone, vinylpyridine, vinylpiperidone, vinylpyrimidine, vinylpiperazine, vinylpyrazine, vinylpyrrole, vinylimidazole, vinyloxazole, vinylmorpholine, N-vinylcarboxylic acid amide, and N-vinylcaprolactam; a maleimide monomer such as N-cyclohexylmaleimide, N-isopropylmaleimide, N-laurylmaleimide, and N-phenylmaleimide; an itaconimide monomer such as N-methylitaconimide, N-ethylitaconimide, N-butylitaconimide, N-octylitaconimide, N-2-ethylhexylitaconimide, N-cyclohexylitaconimide, and N-laurylitaconimide; a succinimide monomer such as N-(meth)acryloyloxymethylene succinimide, N-(meth)acryloyl-6-oxyhexamethylene succinimide, and N-(meth)acryloyl-8-oxyoctamethylene succinimide; a glycol acrylester monomer such as polyethyleneglycol(meth)acrylate, polypropyleneglycol(meth)acrylate, methoxyethyleneglycol(meth)acrylate and methoxypropyleneglycol(meth)acrylate; an acrylic ester monomer having a heterocyclic ring, a halogen atom, a silicon atom, etc. such as tetrahydrofurfuryl(meth)acrylate, fluorine(meth)acrylate, and silicone (meth)acrylate; and a multifunctional monomer such a hexanediol di(meth)acrylate, (poly)ethyleneglycol di(meth)acrylate, (poly) propyleneglycol di(meth)acrylate, neopentylglycol di(meth)acrylate, pentaerythritol di(meth)acrylate, trimethylolpropane tri(meth)acrylate, pentaerythritol tri(meth)acrylate, dipentaerythritol hexa(meth)acrylate, epoxyacrylate, polyesteracrylate, urethaneacrylate, divinylbenzene, butyl di(meth)acrylate, and hexyl di(meth)acrylate. One type or two types or more of these copolymerizable monomer components can be used.

When a radiation curable pressure-sensitive adhesive (or an energy ray curable pressure-sensitive adhesive) is used as the pressure-sensitive adhesive, examples of the radiation curable pressure-sensitive adhesive (composition) include an intrinsic radiation curable pressure-sensitive adhesive in which a polymer having a radical reactive carbon-carbon double bond in the side chain or the main chain, or at the ends of the main chain of the polymer is used as the base polymer, and a radiation curable pressure-sensitive adhesive in which monomer components or oligomer components that are curable by an ultraviolet ray are compounded in the pressure-sensitive adhesive. When a thermoexpandable pressure-sensitive adhesive is used as the pressure-sensitive adhesive, an example of the thermoexpandable pressure-sensitive adhesive includes a thermoexpandable pressure-sensitive adhesive containing a pressure-sensitive adhesive and a foaming agent (especially, thermoexpandable microspheres).

In the first part of the present invention, the pressure-sensitive adhesive may contain various types of additives (for example, a tackifying agent, a coloring agent, a thickening agent, an extender, a filler, a plasticizer, an antiaging agent, an antioxidant, a surfactant, a cross-linking agent, etc.) within the range wherein the effect, etc., of the first part of the present invention is not lost.

The cross-linking agent is not especially limited, and a known cross-linking agent can be used. Specific examples of the cross-linking agent include an isocyanate cross-linking agent, an epoxy cross-linking agent, a melamine cross-linking agent, a peroxide cross-linking agent, a urea cross-linking agent, a metal alkoxide cross-linking agent, a metal chelate cross-linking agent, a metal salt cross-linking agent, a carbodiimide cross-linking agent, an oxazoline cross-linking agent, an aziridine cross-linking agent, and an amine cross-linking agent. The isocyanate cross-linking agent and the epoxy cross-linking agent are preferable. The cross-linking agents may be used either alone or in a combination of two or more types. The use amount of the cross-linking agent is not especially limited.

Examples of the isocyanate cross-linking agent include lower aliphatic polyisocyanates such as 1,2-ethylene diisocyanate, 1,4-butylene diisocyanate, and 1,6-hexamethylene diisocyanate; alicyclic polyisocyanates such as cyclopentylene diisocyanate, cyclohexylene diisocyanate, isophorone diisocyanate, hydrogenated tolylene diisocyanate, and hydrogenated xylene diisocyanate; and aromatic polyisocyanates such as 2,4-tolylene diisocyanate, 2,6-tolylene diisocyanate, 4,4′-diphenylmethane diisocyanate, and xylylene diisocyanate. Besides these, a trimethylolpropane/tolylene diisocyanate trimer adduct [trade name “Coronate L” manufactured by Nippon Polyurethane Industry Co., Ltd.], a trimethylolpropane/hexamethylene diisocyanate trimer adduct [trade name “Coronate HL” manufactured by Nippon Polyurethane Industry Co., Ltd.], etc., can be used. Examples of the epoxy cross-linking agent include N,N,N′N′-tetraglycidyl-m-xylenediamine, diglycidylaniline, 1,3-bis(N,N-glycidylaminomethyl)cyclohexane, 1,6-hexanedioldiglycidylether, neopentylglycol diglycidylether, ethylenglycol diglycidylether, propyleneglycol diglycidylether, polyethylene glycol diglycidylether, polypropyleneglycol diglycidylether, sorbitol polyglycidylether, glycerol polyglycidylether, pentaerythritol polyglycidylether, polyglycerol polyglycidylether, sorbitan polyglycidylether, trimethylolpropane polyglycidylether, adipic diglycidylester, o-phthalic diglycidylester, triglycidyl-tris(2-hydroxyethyl)isocyanurate, resorcin diglycidylether, bisphenol-S-diglycidylether, and an epoxy resin having two or more epoxy groups in the molecule.

In the first part of the present invention, a cross-linking treatment can be performed by irradiating with an electron beam, an ultraviolet ray, etc., in place of using the cross-linking agent or while using the cross-linking agent.

The pressure-sensitive adhesive is mixed with a solvent, other additives, etc. as necessary, and can be formed into a sheet-shaped layer with a traditional method to form the pressure-sensitive adhesive layer. Specific examples of forming the pressure-sensitive adhesive layer include a method of applying the mixture containing the pressure-sensitive adhesive and the solvent and other additives as necessary on the base and a method of applying the mixture on an appropriate separator (such as release paper) to form a pressure-sensitive adhesive layer and transferring this to the base.

The thickness of the pressure-sensitive adhesive layer is not especially limited. However, the thickness is, for example, 5 μm to 300 μm (preferably 5 μm to 200 μm, more preferably 5 μm to 100 μm, and especially preferably 7 μm to 50 μm). When the thickness of the pressure-sensitive adhesive layer is within this range, a reasonable adhesive power can be exhibited. The pressure-sensitive adhesive layer may be either of a single layer or a multilayer.

(Sheet-Shaped Resin Composition)

The sheet-shaped resin composition 16 has a function of sealing the space between a chip 20 (refer to FIG. 6) that is formed by dicing the wafer 11 and a mounting substrate 22 (refer to FIG. 6). An example of the constituting material of the sheet-shaped resin composition 16 is a material in which a thermoplastic resin and a thermosetting resin are used together. The thermosetting resin may be used alone.

Examples of the thermoplastic resin include natural rubber, butyl rubber, isoprene rubber, chloroprene rubber, ethylene/vinyl acetate copolymer, ethylene/acrylic acid copolymer, ethylene/acrylic ester copolymer, polybutadiene resin, polycarbonate resin, thermoplastic polyimide resin, polyamide resins such as 6-nylon and 6,6-nylon, phenoxy resin, acrylic resin, saturated polyester resins such as PET and PBT, polyamideimide resin, and fluorine-contained resin. These thermoplastic resins may be used alone or in a combination of two or more thereof. Of these thermoplastic resins, acrylic resin is particularly preferable since the resin contains ionic impurities in only a small amount and has a high heat resistance so as to make it possible to ensure the reliability of the semiconductor chip.

The acrylic resin is not limited to any particular kind, and may be, for example, a polymer comprising, as a component or components, one or more esters of acrylic acid or methacrylic acid having a linear or branched alkyl group having 30 or less carbon atoms, in particular, 4 to 18 carbon atoms. Examples of the alkyl group include methyl, ethyl, propyl, isopropyl, n-butyl, t-butyl, isobutyl, amyl, isoamyl, hexyl, heptyl, cyclohexyl, 2-ethylhexyl, octyl, isooctyl, nonyl, isononyl, decyl, isodecyl, undecyl, lauryl, tridecyl, tetradecyl, stearyl, octadecyl, and dodecyl groups.

A different monomer which constitutes the above-mentioned polymer is not limited to any particular kind, and examples thereof include carboxyl-containing monomers such as acrylic acid, methacrylic acid, carboxyethyl acrylate, carboxypentyl acrylate, itaconic acid, maleic acid, fumaric acid, and crotonic acid; acid anhydride monomers such as maleic anhydride and itaconic anhydride; hydroxyl-containing monomers such as 2-hydroxyethyl(meth)acrylate, 2-hydroxypropyl(meth)acrylate, 4-hydroxybutyl(meth)acrylate, 6-hydroxyhexyl(meth)acrylate, 8-hydroxyoctyl(meth)acrylate, 10-hydroxydecyl(meth)acrylate, 12-hydroxylauryl(meth)acrylate, and (4-hydroxymethylcyclohexyl)methylacrylate; monomers which contain a sulfonic acid group, such as styrenesulfonic acid, allylsulfonic acid, 2-(meth)acrylamide-2-methylpropanesulfonic acid, (meth)acrylamidepropane sulfonic acid, sulfopropyl(meth)acrylate, and (meth)acryloyloxynaphthalenesulfonic acid; and monomers which contain a phosphoric acid group, such as 2-hydroxyethylacryloyl phosphate.

Examples of the above-mentioned thermosetting resin include phenol resin, amino resin, unsaturated polyester resin, epoxy resin, polyurethane resin, silicone resin, and thermosetting polyimide resin. These resins may be used alone or in a combination of two or more thereof. Particularly preferable is epoxy resin, which contains ionic impurities which corrode semiconductor elements in only a small amount. As the curing agent of the epoxy resin, phenol resin is preferable.

The epoxy resin may be any epoxy resin that is ordinarily used as an adhesive composition. Examples thereof include bifunctional or polyfunctional epoxy resins such as bisphenol A type, bisphenol F type, bisphenol S type, brominated bisphenol A type, hydrogenated bisphenol A type, bisphenol AF type, biphenyl type, naphthalene type, fluorene type, phenol Novolak type, orthocresol Novolak type, tris-hydroxyphenylmethane type, and tetraphenylolethane type epoxy resins; hydantoin type epoxy resins; tris-glycicylisocyanurate type epoxy resins; and glycidylamine type epoxy resins. These may be used alone or in a combination of two or more thereof. Among these epoxy resins, particularly preferable are Novolak type epoxy resin, biphenyl type epoxy resin, tris-hydroxyphenylmethane type epoxy resin, and tetraphenylolethane type epoxy resin, since these epoxy resins are rich in reactivity with phenol resin as an agent for curing the epoxy resin and are superior in heat resistance and so on.

The phenol resin is a resin acting as a curing agent for the epoxy resin. Examples thereof include Novolak type phenol resins such as phenol Novolak resin, phenol aralkyl resin, cresol Novolak resin, tert-butylphenol Novolak resin, and nonylphenol Novolak resin; resol type phenol resins; and polyoxystyrenes such as poly(p-oxystyrene). These may be used alone or in a combination of two or more thereof. Among these phenol resins, phenol Novolak resin and phenol aralkyl resin are particularly preferable, since the sealing reliability can be improved.

About the blend ratio between the epoxy resin and the phenol resin, for example, the phenol resin is blended with the epoxy resin in such a manner that the hydroxyl groups in the phenol resin is preferably from 0.5 to 2.0 equivalents, more preferably from 0.8 to 1.2 equivalents per equivalent of the epoxy groups in the epoxy resin component. If the blend ratio between the two is out of the range, the curing reaction therebetween does not advance sufficiently so that properties of the cured epoxy resin easily deteriorate.

The thermal curing-accelerating catalyst of the epoxy resin and the phenol resin is not particularly limited, and a known thermal curing-accelerating catalyst can be appropriately selected and used. The thermal curing-accelerating catalyst may be used either alone or in a combination of two or more types. Examples of the thermal curing-accelerating catalyst include an amine based curing accelerator, a phosphor based curing accelerator, an imidazole based curing accelerator, a boron based curing accelerator, and a phosphor-boron based curing accelerator.

An inorganic filler may be appropriately incorporated into the sheet-shaped resin composition 16. The incorporation of the inorganic filler makes it possible to confer electric conductance to the sheet, improve the thermal conductivity thereof, and adjust the elasticity.

Examples of the inorganic fillers include various inorganic powders made of the following: a ceramic such as silica, clay, plaster, calcium carbonate, barium sulfate, aluminum oxide, beryllium oxide, silicon carbide, or silicon nitride; a metal such as aluminum, copper, silver, gold, nickel, chromium, lead, tin, zinc, palladium, or solder, or an alloy thereof; and carbon. These may be used alone or in a combination of two or more thereof. Among these, silica, particularly fused silica, is preferably used.

The average particle size of the inorganic filler is preferably 0.1 to 30 μm, and more preferably 0.5 to 25 μm. In the first part of the present invention, inorganic fillers having different average particle sizes can be combined and used together. The average particle size is obtained by a laser diffraction/scattering particle size distribution analyzer (LA-910 manufactured by HORIBA, Ltd.).

The compounded amount of the inorganic filler is preferably 100 to 1400 parts by weight to 100 parts by weight of the organic resin component. It is especially preferably 230 to 900 parts by weight. When the compounded amount of the inorganic filler is 100 parts by weight or more, the heat resistance and the strength improve. When it is 1400 parts by weight or less, the fluidity can be secured. A decrease of the tackiness and the embedding property can thus be prevented.

Other additives besides the inorganic filler can be appropriately compounded in the sheet-shaped resin composition 16 as necessary. Examples of other additives include a flame retardant, a silane coupling agent, and an ion trapping agent, a pigment such as carbon black. Examples of the flame retardant include antimony trioxide, antimony pentaoxide, and brominated epoxy resin. These may be used alone or in a combination of two or more thereof. Examples of the silane coupling agent include β-(3,4-epoxycyclohexyl)ethyltrimethoxysilane, γ-glycidoxypropyltrimethoxysilane, and γ-glycidoxypropylmethyldiethoxysilane. These may be used alone or in a combination of two or more thereof. Examples of the ion trapping agent include hydrotalcite and bismuth hydroxide. These may be used alone or in a combination of two or more thereof. An elastomer component can be added as an additive for adjusting the viscosity to improve the viscosity during curing at high temperature. The elastomer component is not particularly limited as long as it can thicken the resin. However, examples include various acrylic copolymers such as polyacrylic ester; an erastomer having a styrene skeleton such as a polystyrene-polyisobutylene copolymer and a styrene acrylate copolymer; and a rubber copolymer such as a butadiene rubber, a styrene-butadiene rubber (SBR), an ethylene-vinylacetate copolymer (EVA), an isoprene rubber, and acrylonitrile rubber. For the purpose of removing the oxide film on solder at mounting, organic acid may be added.

The viscosity of the sheet-shaped resin composition 16 at 120° C. is preferably 100 Pa·s to 10,000 Pa·s, and more preferably 500 Pa·s to 3,000 Pa·s. When the viscosity is 100 Pa·s or more, large deformation of the shape of the surface at thermal curing can be suppressed. When the viscosity is 10,000 Pa·s or less, insufficient filling of the edge of parts caused by poor fluidity of the resin can be suppressed.

The thickness of the sheet-shaped resin composition 16 (a total thickness when the composition is a multilayer) is not especially limited. However, with consideration for the strength of the resin after the resin is cured and the filling property, the thickness is preferably 100 μm or more and 1,000 μm or less. The thickness of the sheet-shaped resin composition 16 can be appropriately set by considering the width of the space between the chip 20 and the mounting substrate 22.

The sheet-shaped resin composition 16 is produced as follows for example. First, a resin composition solution is produced that is a formation material of the sheet-shaped resin composition 16. As described above, the resin composition, the filler, other various types of additives, etc. are compounded in the resin composition solution.

Next, the resin composition solution is applied on the base separator to have a prescribed thickness to forma coating film. Then, the coating film is dried under a prescribed condition to form the sheet-shaped resin composition 16. The coating method is not especially limited. However, examples include roll coating, screen coating, and gravure coating. For the drying condition, for example, the drying temperature is 70° C. to 160° C. and the drying time is 1 minute to 5 minutes.

(Method of Producing the Dicing Tape-Integrated Sheet-Shaped Resin Composition)

The dicing tape 15 and the sheet-shaped resin composition are pasted together to obtain the dicing tape-integrated sheet-shaped resin composition 14. Pasting can be performed by press bonding for example. At this time, the lamination temperature is not especially limited. However, the lamination temperature is preferably 30° C. to 50° C., and more preferably 35° C. to 45° C. The linear load is not especially limited. However, the linear load is preferably 0.1 kgf/cm to 20 kgf/cm, and more preferably 1 kgf/cm to 10 kgf/cm. Further, the resin composition solution for forming the sheet-shaped resin composition 16 is directly applied on the dicing tape 15 and dried to obtain the dicing tape-integrated sheet-shaped resin composition 14.

[Pasting Step]

Next, the other side 11b of the wafer 10 with a support is pasted to the sheet-shaped resin composition 16 of the dicing tape-integrated sheet-shaped resin composition 14 in the pasting step (Step C). They are pasted together in the form in which the outer peripheral part of the other side 11b of the wafer 11 is not coated with the sheet-shaped resin composition 16 (refer to FIG. 3). Pasting can be performed by press bonding for example. At this time, the lamination temperature is not especially limited. However, the lamination temperature is preferably 20° C. to 120° C., and more preferably 40° C. to 100° C. The pressure is not especially limited. However, the pressure is preferably 0.05 MPa to 1.0 MPa, and more preferably 0.1 MPa to 0.8 MPa. Pasting is preferably performed under reduced pressure. When pasting is performed under reduced pressure, the generation of voids at the interface between the wafer 11 and the sheet-shaped resin composition 16 can be suppressed. As a result, the wafer 11 and the sheet-shaped resin composition 16 can be pasted together more suitably. The reduced pressure condition is preferably 5 Pa to 1,000 Pa, and more preferably 10 Pa to 500 Pa. When the step C is performed under the reduced pressure condition, the step C can be performed in a reduced pressure chamber for example.

[Support Peeling Step]

Next, the temporary fixing layer 13 is dissolved by a solvent to peel the support 12 from the wafer 11 in the support peeling step (Step D) (refer to FIG. 4). At this time, a force may be applied in the direction of peeling the support 12 from the wafer 11 by suctioning the support 12. When the formation material for forming the temporary fixing layer 13 is a polyimide resin, a solvent is preferably used such as N,N-dimethylacetamide (DMAc), N-methyl-2-pyrrolidone (NMP), and N,N-dimethylformamide (DMF). When the formation material for forming the temporary fixing layer 13 is a silicone resin, a solvent is preferably used such as toluene, methylenechloride, and trichloroethane. When the formation material for forming the temporary fixing layer 13 is an aliphatic olefin resin, a solvent is preferably used such as toluene and ethylacetate. When the formation material for forming the temporary fixing layer 13 is a hydrogenated styrene thermoplastic elastomer, a solvent is preferably used such as toluene and ethylacetate. When the formation material for forming the temporary fixing layer 13 is an acrylic resin, a solvent is preferably used such as acetone, methylethylketone, methanol, toluene, and ethylacetate. In the present embodiment, it is preferable that the sheet-shaped resin composition 16 is not easily dissolved by the solvent while the temporary fixing layer 13 is dissolved by the solvent. Examples of the preferred combination of the material of the temporary fixing layer 13, the solvent, and the material of the sheet-shaped resin composition 16 include a combination of a polyimide resin as the temporary fixing layer 13, NMP as the solvent, and epoxy resin as the sheet-shaped resin composition 16 and a combination of an aliphatic olefin resin as the temporary fixing layer 13, toluene as the solvent, and an epoxy resin as the sheet-shaped resin composition 16.

[Dicing Step]

Next, the wafer 11 is diced together with the sheet-shaped resin composition 16 to obtain the chip 20 with the sheet-shaped resin composition 16 in the dicing step (Step E) (refer to FIG. 5). Conventionally known blade dicing and laser dicing can be adopted for dicing.

[Underfill Step]

Next, in the underfill step (Step F), the chip 20 with the sheet-shaped resin composition 16 is arranged on amounting substrate 22, the electrodes of the chip 20 (not shown in the drawing) and the electrodes of the mounting substrate 22 (not shown in the drawing) are bonded with the bump 21 interposed therebetween that is formed on the electrodes of the chip 20, and the space between the chip 20 and the mounting substrate 22 is sealed (under-filled) with the sheet-shaped composition 16 (refer to FIG. 6). Specifically, the sheet-shaped resin composition 16 of the chip 20 with the sheet-shaped resin composition 16 is arranged in opposition to the mounting substrate 22, and pressure is applied from the chip 20 with the sheet-shaped resin composition 16 using a flip-chip bonder. The electrodes of the chip 20 and the electrodes of the mounting substrate 22 are thus bonded with the bump 21 interposed therebetween that is formed on the electrodes of the chip 20, and the space between the chip 20 and the mounting substrate 22 is sealed (under-filled) with the sheet-shaped composition 16. The bonding temperature is preferably 50° C. to 300° C., and more preferably 100° C. to 280° C. The bonding pressure is preferably 0.02 MPa to 10 MPa, and more preferably 0.05 MPa to 5 MPa.

According to the semiconductor device production method of the present embodiment, a semiconductor device can be obtained in which the chip 20 on which a through electrode is formed is mounted to the mounting substrate 22 and the space between the chip 20 and the mounting substrate 22 is sealed with the sheet-shaped composition 16. According to the semiconductor device production method of the present embodiment, because the sheet-shaped resin composition 16 is smaller in outer shape than the other side 11b of the wafer 11, the solvent does not easily flow around the sheet-shaped resin composition 16 when the temporary fixing layer 13 is dissolved by a solvent to peel the support from the wafer. As a result, the dissolution of the sheet-shaped resin composition 16 can be suppressed. As described above, the dissolution of the sheet-shaped resin composition 16 is suppressed, and therefore the sheet-shaped resin composition 16 of the chip 20 with the sheet-shaped resin composition 16 that is obtained in the step E sufficiently functions as a sheet-shaped resin composition for sealing the space between the chip 20 and the mounting substrate 22. Because the dissolution of the sheet-shaped resin composition 16 is suppressed, the yield ratio of the semiconductor device that is obtained in the step F (a semiconductor device in which the space between the chip and the mounting substrate is sealed with the sheet-shaped composition) can be improved.

In this embodiment, a case is explained in which the sheet-shaped resin composition 16 is laminated on the dicing tape 15 that is planar. However, the lamination form of the sheet-shaped resin composition and the dicing tape is not limited to this example in the first part of the present invention, and the sheet-shaped resin composition may be embedded in the dicing tape for example. The entire sheet-shaped resin composition may be embedded or the sheet-shaped resin composition may be partially embedded.

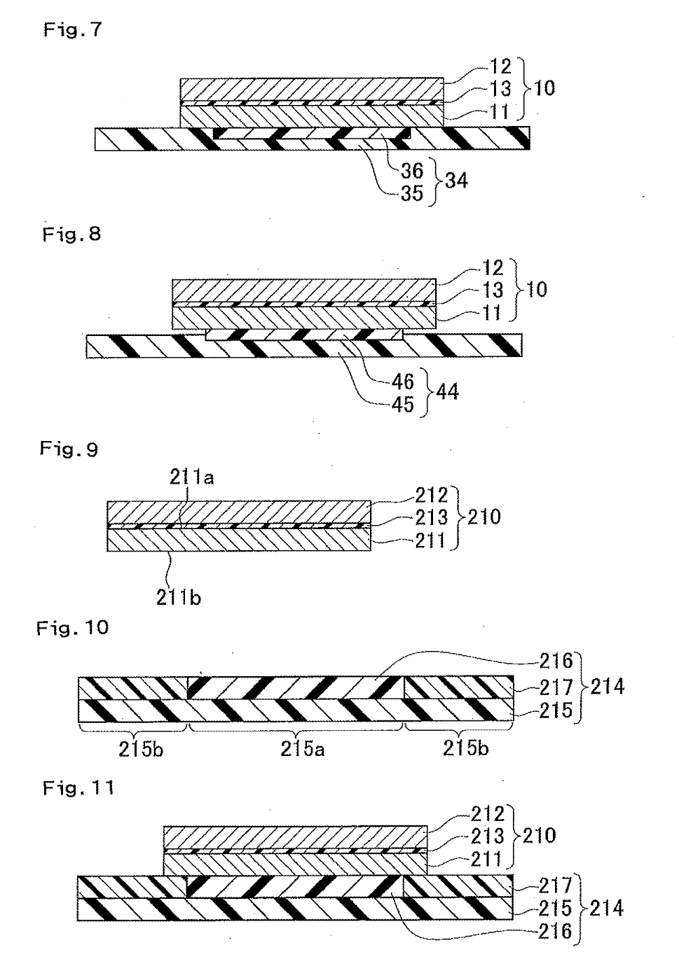

FIGS. 7 and 8 are schematic cross sectional drawings for explaining the semiconductor device production method according to other embodiments. A dicing tape-integrated sheet-shaped resin composition 34 shown in FIG. 7 is laminated on a dicing tape 35 in the form that the entire sheet-shaped resin composition 36 is embedded in the dicing tape 35. A dicing tape-integrated sheet-shaped resin composition 44 shown in FIG. 8 is laminated on a dicing tape 45 in the form that the entire sheet-shaped resin composition 46 is embedded in the dicing tape 45. An example of the method of manufacturing the dicing tape-integrated sheet-shaped resin compositions 34 or 44 is a method of forming a pressure-sensitive adhesive layer on a base, cutting the pressure-sensitive adhesive layer in conformity with the shape of the sheet-shaped resin compositions 36 or 46, and pasting the sheet-shaped resin compositions 36 or 46 to the portion where the pressure-sensitive adhesive layer is cut out. Another example is a method of forming a pressure-sensitive adhesive layer on the portion of the base where the sheet-shaped resin compositions 36 or is not formed and pasting thereto the sheet-shaped resin compositions 36 or 46. Whether the entire sheet-shaped resin composition is embedded or the sheet-shaped resin composition is partially embedded in the dicing tape can be adjusted by the thickness of the portion that is cut out, etc. Because the dicing tape 35 or 45 can be formed using the material that is the same as the dicing tape 15, the explanation of the material is omitted. Because the sheet-shaped resin composition 36 or 46 can be formed using the material that is the same as the sheet-shaped resin composition 16, the explanation of the material is omitted. When the entire sheet-shaped resin composition is embedded in the dicing tape or the sheet-shaped resin composition is partially embedded, it becomes more difficult for the sheet-shaped resin composition 36 to make contact with the solvent. As a result, the dissolution of the sheet-shaped resin composition is further suppressed.

The method of embedding the sheet-shaped resin composition in the dicing tape is not limited by the method of cutting out the dicing tape and pasting the sheet-shaped resin composition to the portion where the dicing tape is cut out. A dicing tape-integrated sheet-shaped resin composition in which a planar sheet-shaped resin composition is pasted to a planar dicing tape and a wafer with a support may be clamped together, and the sheet-shaped resin composition may be embedded in the dicing tape by the pressure created by clamping.

The embodiments according to the first part of the present invention were explained above.

### Second Part of the Present Invention

Below, the points of the second part of the present invention that are different from the first part of the present invention are explained. For the characteristics and effects other than those specifically explained in the second part of the present invention, the semiconductor device production method, the sheet-shaped resin composition, and the dicing tape-integrated sheet-shaped resin composition of the second part of the present invention can exhibit the characteristics and effects that are the same as those of the semiconductor device production method, the sheet-shaped resin composition, and the dicing tape-integrated sheet-shaped resin composition of the first part of the present invention within the range of not being contrary to the purpose of the second part of the present invention.

Below, the embodiment of the second part of the preset invention is explained with reference to the drawings. FIGS. 9 to 14 are schematic cross sectional drawings for explaining the semiconductor device production method according to one embodiment of the second part of the present invention.

The semiconductor device production method according to the present embodiment has at least a step A2 of preparing a wafer with a support including a wafer, a temporary fixing layer, and a support bonded to one side of the wafer, on which a through electrode is formed, with the temporary fixing layer interposed therebetween (a wafer with a support preparing step), a step B2 of preparing a dicing tape-integrated sheet-shaped resin composition having a dicing tape, a sheet-shaped resin composition that is laminated on the center of the dicing tape, and a barrier layer that is laminated on the region outside of the center of the dicing tape (a dicing tape-integrated sheet-shaped resin composition preparing step), a step C2 of pasting the other side of the wafer with a support to the sheet-shaped resin composition of the dicing tape-integrated sheet-shaped resin composition (a pasting step), and a step D2 of dissolving the temporary fixing layer by a solvent to peel the support from the wafer (a support peeling step).

[Wafer with a Support Preparing Step]

In the wafer with a support preparing step (Step A2), first, a wafer 210 with a support, which includes a wafer 211, a temporary fixing layer 213, and a support 212 bonded to one side 211a of a wafer 211, on which a through electrode (not shown in the drawing) is formed, with the temporary fixing layer 213 interposed therebetween (refer to FIG. 9), is prepared. For example, the wafer 210 with a support can be obtained with a step of bonding the circuit forming side of a wafer having a circuit forming side and a non-circuit-forming side (backside) to the support 212 with a temporary fixing layer 213 interposed therebetween (a support bonding step), a step of grinding the non-circuit-forming side of the wafer that is bonded to the support 212 (a wafer backside grinding step), and a step of performing processes (for example, forming the TSV (through electrode), forming an electrode, and forming a metal wiring) on the grinded non-circuit-forming side of the wafer (a non-circuit-forming side processing step). More specifically, examples of the step of performing processes on the non-circuit-forming side of the wafer are conventionally known processes such as metal sputtering for forming an electrode, etc., wet etching for etching the metal sputtering layer, pattern formation by applying, exposing, and developing the resist to produce a mask for forming the metal wiring, peeling of the resist, dry etching, formation of metal plating, silicon etching for forming the TSV, and formation of an oxide film on the surface of silicon. The support 212 is bonded to the wafer 211 to secure the strength of the wafer when the wafer is grinded. The step of performing the processes described above includes processes at high temperature (for example, 250° C. or more). Therefore, a material having a certain level of strength and heat resistance (for example, a heat resistant glass) is used for the support 212.

(Support)

The support 12 that is explained in the first part of the present invention can be used as the support 212.

(Wafer)

The wafer 11 that is explained in the first part of the present invention can be used as the wafer 211.

(Temporary Fixing Layer)

The adhesive composition that constitutes the temporary fixing layer 213 is not especially limited as long as the adhesive composition which is selected does not peel from the support 212 and the wafer 211 when performing the step of grinding the backside of the wafer and the step of performing processes on the non-circuit-forming side, and is dissolvable with a solvent to peel the support 212 from the wafer 211 in the step D2 (the support peeling step). The formation material for forming the temporary fixing layer 13 that is explained in the first part of the present invention can be used as the formation material for forming the temporary fixing layer 213.

The same method as the method of producing the temporary fixing layer 13 that is explained in the first part of the present invention can be adopted as the method of producing the temporary fixing layer 213.

The same method as the method of producing the wafer 10 with a support in which the wafer 11 and the support 12 are bonded together with the temporary fixing layer 13 interposed therebetween, that is explained in the first part of the present invention, can be adopted as the method of producing the wafer 210 with a support in which the wafer 211 and the support 212 are bonded together with the temporary fixing layer 213 interposed therebetween.

[Dicing Tape-Integrated Sheet-Shaped Resin Composition Preparing Step]

Next, in the dicing tape-integrated sheet-shaped resin composition preparing step (Step B2), a dicing tape-integrated sheet-shaped resin composition 214 having a dicing tape 215, a sheet-shaped resin composition 216 (a sheet-shaped resin composition 216 for under-filling) that is laminated on the center 215a of the dicing tape 215, and a barrier layer 217 that is laminated on the region 215b outside of the center 215a of the dicing tape 215 (refer to FIG. 10), is prepared. The dicing tape-integrated sheet-shaped resin composition 214 may be prepared such that the dicing tape 215, the sheet-shaped resin composition 216, and the barrier layer 217 are pasted together in advance, or may be prepared such that the dicing tape 215, the sheet-shaped resin composition 216, and the barrier layer 217 are separately prepared and these are pasted together. The shape of the sheet-shaped resin composition 216 is not especially limited, and may be circular, rectangular, etc. The outer shape of the sheet-shaped resin composition 216 is not especially limited. However, the outer shape is preferably the same as an outer shape of the other side 211b of the wafer 211 or smaller than the outer shape of the other side 211b of the wafer 211. When an outer shape of the sheet-shaped resin composition 216 is smaller than an outer shape of the other side 211b of the wafer 211, in the pasting step (Step C2) described later, the other side 211b of the wafer 210 with a support is pasted on the sheet-shaped resin composition 216 of the dicing tape-integrated sheet-shaped resin composition 214 in the form in which the outer peripheral part of the wafer 211 is laminated on the barrier layer 217. The sheet-shaped resin composition 216 that is smaller in outer shape than the other side 211b of the wafer 211 means the sheet-shaped resin composition 216 having a shape in which the outer peripheral part of the other side 211b of the wafer 211 is not coated with the sheet-shaped resin composition 216 when the wafer 211 is pasted. An example of the shape of the sheet-shaped resin composition 216 is a round shape having smaller diameter than the wafer 211 (for example, the diameter of the sheet-shaped resin composition 216 is 280 mm) when the wafer 211 has a round shape (for example, the diameter of the wafer 211 is 290 mm). In this case, the wafer 211 and the sheet-shaped resin composition 216 are preferably laminated so that the centers are aligned. In the present embodiment, the case is explained in which an outer shape of the sheet-shaped resin composition 216 is smaller than an outer shape of the other side 211b of the wafer 211.

(Dicing Tape)

The dicing tape 15 that is explained in the first part of the present invention can be used as the dicing tape 215.

(Sheet-Shaped Resin Composition)

The sheet-shaped resin composition 216 has a function of sealing the space between a chip 220 that is formed by dicing the wafer 211 (refer to FIG. 14) and a mounting substrate 222 (refer to FIG. 14). Examples of the constituting materials of the sheet-shaped resin composition 216 are the constituting materials of the sheet-shaped resin composition 16 that are explained in the first part of the present invention.

The same method of producing the sheet-shaped resin composition 16 that is explained in the first part of the present invention can be adopted as the method of producing the sheet-shaped resin composition 216.

(Barrier Layer)

The barrier layer 217 is formed to cover at least part of the side of the sheet-shaped resin composition 216, and has a function of protecting the sheet-shaped resin composition 216 from dissolving in the solvent that is used in the support peeling step (Step D2). It is preferable that the constituting materials of the barrier layer 217 do not easily dissolve in the solvent that is used in the step D2 (the support peeling step) described later. Examples of the constituting materials for forming the barrier layer 217 include an acrylic resin, a silicone resin, metal, and inorganic substance. For example, the acrylic resin and the silicone resin that are the same as those of the pressure-sensitive layer constituting the dicing tape 215 can be used.

The thickness of the barrier layer 217 (a total thickness when the barrier layer is a multilayer) is not especially limited. However, the thickness is preferably the same as or smaller than the thickness of the sheet-shaped resin composition 216 (for example, 5 μm to 10 μm smaller than the thickness of the sheet-shaped resin composition 216) when the side of the sheet-shaped resin composition 216 is considered to not contact the solvent. The thickness of the barrier layer 217 may be larger than the thickness of the sheet-shaped resin composition 216. This is because at least part of the side of the sheet-shaped resin composition can be made not to contact the solvent even when the thickness of the barrier layer 217 is smaller than the thickness of the sheet-shaped resin composition 216.

(Method of Producing a Dicing Tape-Integrated Sheet-Shaped Resin Composition)

The sheet-shaped resin composition 216 is formed into a size corresponding to the center 215a in advance, the barrier layer 217 is formed into a size corresponding to the outside region 215b, and these are pasted to the dicing tape 215 to obtain the dicing tape-integrated sheet-shaped resin composition 214 according to the present embodiment. Pasting can be performed by press bonding for example. At this time, the lamination temperature is not especially limited. However, the lamination temperature is preferably 30° C. to 50° C., and more preferably 35° C. to 45° C. The linear load is not especially limited. However, the linear load is preferably 0.1 kgf/cm to 20 kgf/cm, and more preferably 1 kgf/cm to 10 kgf/cm. Further, the resin composition solution for forming the sheet-shaped resin composition 216 and the solution for forming the barrier layer 217 may be directly applied on the dicing tape 215 and dried to obtain the dicing tape-integrated sheet-shaped resin composition 214.

[Pasting Step]

Next, the other side 211b of the wafer 210 with a support is pasted to the sheet-shaped resin composition 216 of the dicing tape-integrated sheet-shaped resin composition 214 in the pasting step (Step C2). They are pasted together in the form in which the outer peripheral part of the other side 211b of the wafer 211 is not coated with the sheet-shaped resin composition 216 (refer to FIG. 11). Because an outer shape of the sheet-shaped resin composition 216 is smaller than an outer shape of the other side 211b of the wafer 211, the other side 211b of the wafer 210 with a support is pasted to the sheet-shaped resin composition 216 of the dicing tape-integrated sheet-shaped resin composition 214 in the form in which the outer peripheral part of the wafer 211 is laminated on the barrier layer 217 in the present embodiment. It is therefore more difficult for the sheet-shaped resin composition 216 to make contact with the solvent. Pasting can be performed by press bonding for example. At this time, the lamination temperature is not especially limited. However, the lamination temperature is preferably 20° C. to 120° C., and more preferably 40° C. to 100° C. The pressure is not especially limited. However, the pressure is preferably 0.05 MPa to 1.0 MPa, and more preferably 0.1 MPa to 0.8 MPa. Pasting is preferably performed under reduced pressure. When pasting is performed under reduced pressure, the generation of voids at the interface between the wafer 211 and the sheet-shaped resin composition 216 can be suppressed. As a result, the wafer 211 and the sheet-shaped resin composition 216 can be pasted together more suitably. The reduced pressure condition is preferably 5 Pa to 1,000 Pa, and more preferably 10 Pa to 500 Pa. When the step C2 is performed under the reduced pressure condition, the step C2 can be performed in a reduced pressure chamber for example.

[Support Peeling Step]

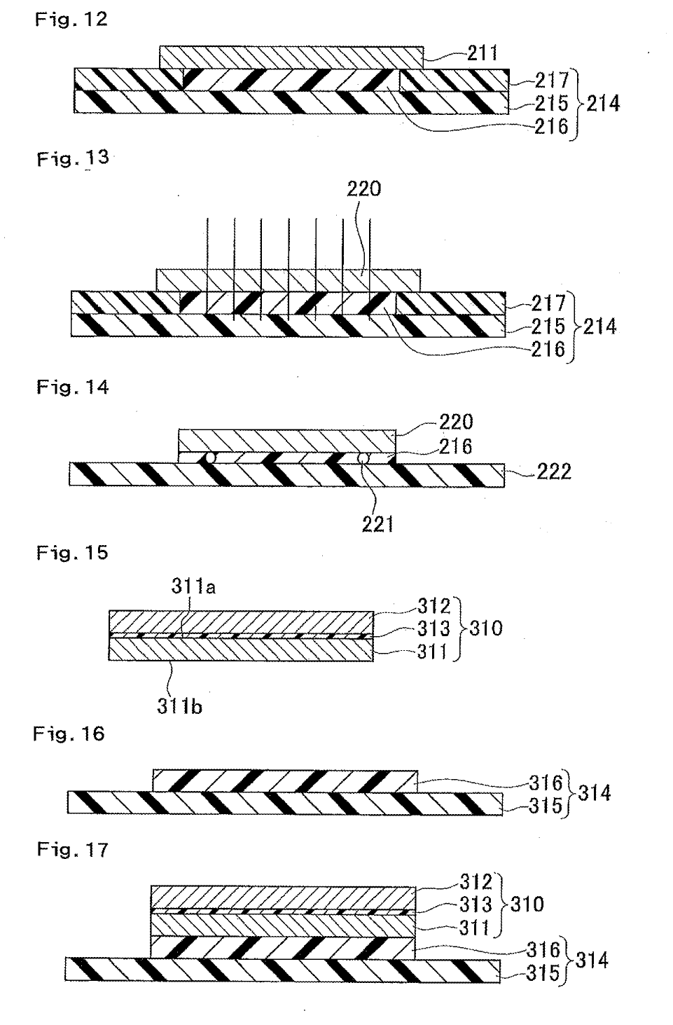

Next, the temporary fixing layer 213 is dissolved by a solvent to peel the support 212 from the wafer 211 in the support peeling step (Step D2) (refer to FIG. 12). At this time, a force may be applied in the direction of peeling the support 212 from the wafer 211 by suctioning the support 212. When the formation material for forming the temporary fixing layer 213 is a polyimide resin, a solvent is preferably used such as N,N-dimethylacetamide (DMAc), N-methyl-2-pyrrolidone (NMP), and N,N-dimethylformamide (DMF). When the formation material for forming the temporary fixing layer 213 is a silicone resin, a solvent is preferably used such as toluene, methylenechloride, and trichloroethane. When the formation material for forming the temporary fixing layer 213 is an aliphatic olefin resin, a solvent is preferably used such as toluene and ethylacetate. When the formation material for forming the temporary fixing layer 213 is a hydrogenated styrene thermoplastic elastomer, a solvent is preferably used such as toluene and ethylacetate. When the formation material for forming the temporary fixing layer 213 is an acrylic resin, a solvent is preferably used such as acetone, methylethylketone, methanol, toluene, and ethylacetate. In the present embodiment, it is preferable that the sheet-shaped resin composition 216 and the barrier layer 217 are not easily dissolved by the solvent while the temporary fixing layer 213 is dissolved by the solvent. Examples of the preferred combination of the material of the temporary fixing layer 213, the solvent, the material of the sheet-shaped resin composition 216, and the material of the barrier layer 217 include a combination of a polyimide resin as the temporary fixing layer 213, NMP as the solvent, an epoxy resin as the sheet-shaped resin composition 216, and an acrylic resin for the barrier layer 217 and a combination of an aliphatic olefin resin as the temporary fixing layer 213, toluene as the solvent, an epoxy resin as the sheet-shaped resin composition 216, and a polyimide resin as the barrier layer 217.

[Dicing Step]

Next, the wafer 211 is diced together with the sheet-shaped resin composition 216 to obtain the chip 220 with the sheet-shaped resin composition 216 in the dicing step (Step E2) (refer to FIG. 13). Conventionally known blade dicing and laser dicing can be adopted for dicing.

[Underfill Step]

Next, in the underfill step (Step F2), the chip 220 with the sheet-shaped resin composition 216 is arranged on amounting substrate 222, the electrodes of the chip 220 (not shown in the drawing) and the electrodes of the mounting substrate 222 (not shown in the drawing) are bonded with the bump 221, that is interposed therebetween and is formed on the electrodes of the chip 220, and the space between the chip 220 and the mounting substrate 222 is sealed (under-filled) with the sheet-shaped composition 216 (refer to FIG. 14). Specifically, the sheet-shaped resin composition 216 of the chip 220 with the sheet-shaped resin composition 216 is arranged in opposition to the mounting substrate 222, and pressure is applied from the chip 220 with the sheet-shaped resin composition 216 using a flip-chip bonder. The electrodes of the chip 220 and the electrodes of the mounting substrate 222 are thus bonded with the bump 221 that is interposed therebetween and is formed on the electrodes of the chip 220, and the space between the chip 220 and the mounting substrate 222 is sealed (under-filled) with the sheet-shaped composition 216. The bonding temperature is preferably 50° C. to 300° C., and more preferably 100° C. to 280° C. The bonding pressure is preferably 0.02 MPa to 10 MPa, and more preferably 0.05 MPa to 5 MPa.

According to the semiconductor device production method of the present embodiment, a semiconductor device can be obtained in which the chip 220 on which a through electrode is formed is mounted to the mounting substrate 222 and the space between the chip 220 and the mounting substrate 222 is sealed with the sheet-shaped composition 216. According to the semiconductor device production method of the present embodiment, because the barrier layer 217 is laminated on the region 215b outside of the center 215a of the dicing tape 215, at least a portion of the side of the sheet-shaped resin composition 216 laminated on the center 215a of the dicing tape 215 is covered with the barrier layer 217. Therefore, when the temporary fixing layer 213 is dissolved by a solvent to peel the support 212 from the wafer 211, it is difficult for the solvent to make contact with the sheet-shaped resin composition. As a result, dissolution of the sheet-shaped resin composition 216 can be suppressed. As described above, the dissolution of the sheet-shaped resin composition 216 is suppressed, and therefore the sheet-shaped resin composition 216 of the chip 220 with the sheet-shaped resin composition 216 that is obtained in the step E2 sufficiently functions as a sheet-shaped resin composition for sealing the space between the chip 220 and the mounting substrate 222. Because the dissolution of the sheet-shaped resin composition 216 is suppressed, the yield ratio of the semiconductor device that is obtained in the step F2 (a semiconductor device in which the space between the chip and the mounting substrate is sealed with the sheet-shaped composition) can be improved.

In this embodiment, a case is explained in which an outer shape of the sheet-shaped resin composition 216 is smaller than an outer shape of the other side 211b of the wafer 211. However, an outer shape of the sheet-shaped resin composition of the second part of the present invention may be the same as an outer shape of the other side of the wafer. Because the sheet-shaped resin composition is covered with the other side of the wafer and the barrier layer even when both outer shapes are the same, it is possible to avoid contact between the sheet-shaped resin composition and the solvent.

In this embodiment, a case is explained in which the barrier layer 217 is not peeled off from the dicing tape 215. However, the second part of the present invention is not limited by this example, and the barrier layer may be peeled off from the dicing tape after the step D2 (the support peeling step) (for example, after the step D2 and before the dicing step). The case in which the barrier layer is peeled off from the dicing tape after the step D2 (the support peeling step) is superior in suppression of contamination of the semiconductor element by the barrier layer as compared with the case in which the barrier layer is not peeled off.

The embodiment according to the second part of the present invention was explained above.

### Third Part of the Present Invention

Below, the points of the third part of the present invention that are different from the first part of the present invention are explained. For the characteristics and effects other than those specifically explained in the third part of the present invention, the semiconductor device production method, the sheet-shaped resin composition, and the dicing tape-integrated sheet-shaped resin composition of the third part of the present invention can exhibit the characteristics and effects that are the same as those of the semiconductor device production method, the sheet-shaped resin composition, and the dicing tape-integrated sheet-shaped resin composition of the first part of the present invention within the range of not being contrary to the purpose of the second part of the present invention.

Below, the embodiment of the third part of the preset invention is explained with reference to the drawings. FIGS. 15 to 21 are schematic cross sectional drawings for explaining the semiconductor device production method according to one embodiment of the third part of the present invention.

The semiconductor device production method according to the present embodiment includes at least a step A3 of preparing a wafer with a support including a wafer, a temporary fixing layer, and a support bonded to one side of the wafer, on which a through electrode is formed, with the temporary fixing layer interposed therebetween (a wafer with a support preparing step), a step B3 of preparing a dicing tape-integrated sheet-shaped resin composition including a dicing tape and a sheet-shaped resin composition formed on the dicing tape (a dicing tape-integrated sheet-shaped resin composition preparing step), a step C3 of pasting the other side of the wafer with a support to the sheet-shaped resin composition of the dicing tape-integrated sheet-shaped resin composition (a pasting step), a step D3 of applying an adhesive to the portion where the sheet-shaped resin composition is exposed after the step C3 (an adhesive applying step), and a step E3 of dissolving the temporary fixing layer by a solvent to peel the support from the wafer (a support peeling step).

[Wafer with a Support Preparing Step]

In the wafer with a support preparing step (Step A3), first, a wafer 310 with a support, which includes a wafer 311, a temporary fixing layer 313, and a support 312 bonded to one side 311a of a wafer 311, on which a through electrode (not shown in the drawing) is formed, with the temporary fixing layer 313 interposed therebetween (refer to FIG. 15), is prepared. For example, the wafer 310 with a support can be obtained with a step of bonding the circuit forming side of a wafer having a circuit forming side and a non-circuit-forming side (backside) to the support 312 with a temporary fixing layer 313 interposed therebetween (a support bonding step), a step of grinding the non-circuit-forming side of the wafer that is bonded to the support 312 (a wafer backside grinding step), and a step of performing processes (for example, forming the TSV (through electrode), forming an electrode, and forming a metal wiring) on the grinded non-circuit-forming side of the wafer (a non-circuit-forming side processing step). More specifically, examples of the step of performing processes on the non-circuit-forming side of the wafer are conventionally known processes such as metal sputtering for forming an electrode, etc., wet etching for etching the metal sputtering layer, pattern formation by applying, exposing, and developing resist to produce a mask for forming the metal wiring, peeling of the resist, dry etching, formation of metal plating, silicon etching for forming the TSV, and formation of an oxide film on the surface of silicon. The support 312 is bonded to the wafer 311 to secure the strength of the wafer when the wafer is grinded. The step of performing the processes described above includes processes at high temperature (for example, 250° C. or more). Therefore, a material having a certain level of strength and heat resistance (for example, a heat resistant glass) is used for the support 312. A material having a certain level of strength and heat resistance (for example, a heat resistant glass) is used.

(Support)

The support 12 that is explained in the first part of the present invention can be used as the support 312.

(Wafer)

The wafer 11 that is explained in the first part of the present invention can be used as the wafer 311.

(Temporary Fixing Layer)

The adhesive composition that constitutes the temporary fixing layer 313 is not especially limited as long as the adhesive composition which is selected does not peel from the support 312 and the wafer 311 when performing the step of grinding the backside of the wafer and the step of performing processes on the non-circuit-forming side, and is dissolvable by a solvent to peel the support 312 from the wafer 311 in the step E3 (the support peeling step). The formation material for forming the temporary fixing layer 13 that is explained in the first part of the present invention can be used as the formation material for forming the temporary fixing layer 313.

The same method as the method of producing the temporary fixing layer 13 that is explained in the first part of the present invention can be adopted as the method of producing the temporary fixing layer 313.

The same method as the method of producing the wafer 10 with a support in which the wafer 11 and the support 12 are bonded together with the temporary fixing layer 13 interposed therebetween, that is explained in the first part of the present invention, can be adopted as the method of producing the wafer 310 with a support in which the wafer 311 and the support 312 are bonded together with the temporary fixing layer 313 interposed therebetween.

[Dicing Tape-Integrated Sheet-Shaped Resin Composition Preparing Step]

Next, in the dicing tape-integrated sheet-shaped resin composition preparing step (Step B3), a dicing tape-integrated sheet-shaped resin composition 314 having a dicing tape 315 and a sheet-shaped resin composition 316 formed on the dicing tape 315 (refer to FIG. 16) is prepared. The dicing tape-integrated sheet-shaped resin composition 314 may be prepared such that the dicing tape 315 and the sheet-shaped resin composition 316 are pasted together in advance, or may be prepared such that the dicing tape 315 and the sheet-shaped resin composition 316 are separately prepared and these are pasted together. The shape of the sheet-shaped resin composition 316 is not especially limited. However, the shape may be circular, rectangular, etc. The size and the shape of the sheet-shaped resin composition are not especially limited. For example, when the wafer 311 has a round shape (for example, the diameter of the wafer 311 is 290 mm), the sheet-shaped resin composition may have a round shape smaller in diameter than the wafer 311 (for example, the diameter of the sheet-shaped resin composition 316 is 280 mm), a round shape that is the same in diameter as the wafer 311, or a round shape larger in diameter than the wafer 311 (for example, the diameter of the sheet-shaped resin composition 316 is 300 mm). Regardless of the shape of the sheet-shaped resin composition 316, it is possible to avoid contact between the sheet-shaped resin composition 316 and the solvent as long as the adhesive is applied to the portion where the sheet-shaped resin composition 316 is exposed in the step of applying an adhesive (Step D3) described later. In this case, the wafer 311 and the sheet-shaped resin composition 316 are preferably laminated so that the centers are aligned. In the present embodiment, the case is explained in which an outer shape of the sheet-shaped resin composition 316 is the same as an outer shape of the other side 311b of the wafer 311.

(Dicing Tape)

The dicing tape 15 that is explained in the first part of the present invention can be used as the dicing tape 315.

(Sheet-Shaped Resin Composition)

The sheet-shaped resin composition 316 has a function of sealing the space between a chip 320 that is formed by dicing the wafer 311 (refer to FIG. 21) and a mounting substrate 322 (refer to FIG. 21). Examples of the constituting materials of the sheet-shaped resin composition 316 are the constituting materials of the sheet-shaped resin composition 16 that are explained in the first part of the present invention.

The same method of producing the sheet-shaped resin composition 16 that is explained in the first part of the present invention can be adopted as the method of producing the sheet-shaped resin composition 316.

(Method of Producing a Dicing Tape-Integrated Sheet-Shaped Resin Composition)

The dicing tape 315 and the sheet-shaped resin composition 316 are pasted together to obtain the dicing tape-integrated sheet-shaped resin composition 314 according to the present embodiment. Pasting can be performed by press bonding for example. At this time, the lamination temperature is not especially limited. However, the lamination temperature is preferably 30° C. to 50° C., and more preferably 35° C. to 45° C. The linear load is not especially limited. However, the linear load is preferably 0.1 kgf/cm to 20 kgf/cm, and more preferably 1 kgf/cm to 10 kgf/cm. Further, the resin composition solution for forming the sheet-shaped resin composition 316 may be directly applied on the dicing tape 315 and dried to obtain the dicing tape-integrated sheet-shaped resin composition 314.

[Pasting Step]

Next, the other side 311b of the wafer 310 with a support is pasted to the sheet-shaped resin composition 316 of the dicing tape-integrated sheet-shaped resin composition 314 in the pasting step (Step C3) (refer to FIG. 17). Pasting can be performed by press bonding for example. At this time, the lamination temperature is not especially limited. However, the lamination temperature is preferably 20° C. to 120° C., and more preferably 40° C. to 100° C. The pressure is not especially limited. However, the pressure is preferably 0.05 MPa to 1.0 MPa, and more preferably 0.1 MPa to 0.8 MPa. Pasting is preferably performed under reduced pressure. When pasting is performed under reduced pressure, the generation of voids at the interface between the wafer 311 and the sheet-shaped resin composition 316 can be suppressed. As a result, the wafer 311 and the sheet-shaped resin composition 316 can be pasted together more suitably. The reduced pressure condition is preferably 5 Pa to 1,000 Pa, and more preferably 10 Pa to 500 Pa. When the step C3 is performed under the reduced pressure condition, the step C3 can be performed in a reduced pressure chamber for example.

[Adhesive Applying Step]

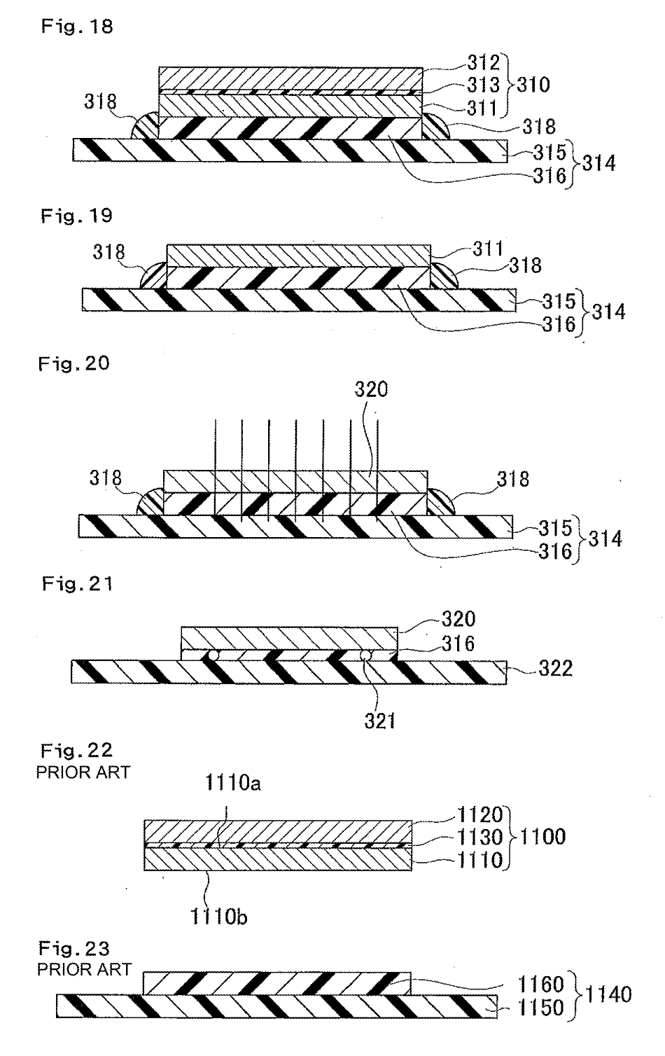

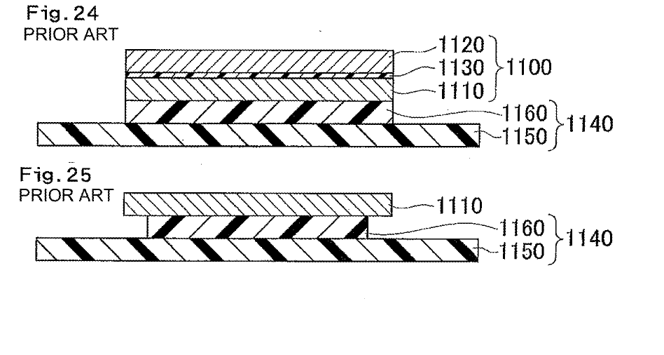

Next, an adhesive 318 is applied to the portion where the sheet-shaped resin composition 316 is exposed in the adhesive applying step (Step D3) (refer to FIG. 18). The adhesive 318 is preferably applied to the entire portion where the sheet-shaped resin composition 316 is exposed. However, the third part of the present invention is not limited by this example, and the adhesive 318 may at least be applied at apart of the area where the sheet-shaped resin composition 316 is exposed. When the adhesive 318 is at least applied at a part of the area where the sheet-shaped resin composition 316 is exposed, it is possible to avoid contact between the sheet-shaped resin composition 316 and the solvent. The adhesive 318 may be applied not only to cover the portion where the sheet-shaped resin composition 316 is exposed but also to cover the dicing tape 315 as well.

(Adhesive)

It is preferable that the constituting materials of the adhesive 318 do not easily dissolve in the solvent that is used in the step E3 (the support peeling step) described later. Examples of the constituting materials for forming the adhesive 318 include an acrylic resin, a silicone resin, metal, and inorganic substance. For example, the acrylic resin and the silicone resin that are the same as those of the pressure-sensitive adhesive layer constituting the dicing tape 315 can be used.

[Support Peeling Step]

Next, the temporary fixing layer 313 is dissolved by the solvent to peel the support 312 from the wafer 311 in the support peeling step (Step E3) (refer to FIG. 19). At this time, a force may be applied in the direction of peeling the support 312 from the wafer 311 by suctioning the support 312. When the formation material for forming the temporary fixing layer 313 is a polyimide resin, a solvent is preferably used such as N,N-dimethylacetamide (DMAc), N-methyl-2-pyrrolidone (NMP), and N,N-dimethylformamide (DMF). When the formation material for forming the temporary fixing layer 313 is a silicone resin, a solvent is preferably used such as toluene, methylenechloride, and trichloroethane. When the formation material for forming the temporary fixing layer 313 is an aliphatic olefin resin, a solvent is preferably used such as toluene and ethylacetate. When the formation material for forming the temporary fixing layer 313 is a hydrogenated styrene thermoplastic elastomer, a solvent is preferably used such as toluene and ethylacetate. When the formation material for forming the temporary fixing layer 313 is an acrylic resin, a solvent is preferably used such as acetone, methylethylketone, methanol, toluene, and ethylacetate. In the present embodiment, it is preferable that the sheet-shaped resin composition 316 is not easily dissolved by the solvent while the temporary fixing layer 313 is dissolved by the solvent. Examples of the preferred combination of the material of the temporary fixing layer 313, the solvent, and the material of the sheet-shaped resin composition 316 include a combination of a polyimide resin as the temporary fixing layer 313, NMP as the solvent, and an epoxy resin as the sheet-shaped resin composition 316, and a combination of an aliphatic olefin resin as the temporary fixing layer 313, toluene as the solvent, and an epoxy resin as the sheet-shaped resin composition 316. In the present embodiment, it is preferable that the sheet-shaped resin composition 316 and the adhesive 318 are not easily dissolved by the solvent while the temporary fixing layer 313 is dissolved by the solvent. Examples of the preferred combination of the material of the temporary fixing layer 313, the solvent, the material of the sheet-shaped resin composition 316, and the material of the adhesive 318 include a combination of a polyimide resin as the temporary fixing layer 313, NMP as the solvent, an epoxy resin as the sheet-shaped resin composition 316, and an acrylic resin as the adhesive 318, and a combination of an aliphatic olefin resin as the temporary fixing layer 313, toluene as the solvent, an epoxy resin as the sheet-shaped resin composition 316, and a polyimide resin as the adhesive 318.

[Dicing Step]

Next, the wafer 311 is diced together with the sheet-shaped resin composition 316 to obtain the chip 320 with the sheet-shaped resin composition 316 in the dicing step (Step F3) (refer to FIG. 20). Conventionally known blade dicing and laser dicing can be adopted for dicing.

[Underfill Step]

Next, in the underfill step (Step G3), the chip 320 with the sheet-shaped resin composition 316 is arranged on amounting substrate 322, the electrodes of the chip 320 (not shown in the drawing) and the electrodes of the mounting substrate 322 (not shown in the drawing) are bonded with the bump 221 interposed therebetween that is formed on the electrodes of the chip 320, and the space between the chip 320 and the mounting substrate 322 is sealed (under-filled) with the sheet-shaped composition 316 (refer to FIG. 21). Specifically, the sheet-shaped resin composition 316 of the chip 320 with the sheet-shaped resin composition 316 is arranged in opposition to the mounting substrate 322, and pressure is applied from the chip 320 with the sheet-shaped resin composition 316 using a flip-chip bonder. The electrodes of the chip 320 and the electrodes of the mounting substrate 322 are thus bonded with the bump 321 interposed therebetween that is formed on the electrodes of the chip 220, and the space between the chip 320 and the mounting substrate 322 is sealed (under-filled) with the sheet-shaped composition 316. The bonding temperature is preferably 50° C. to 300° C., and more preferably 100° C. to 280° C. The bonding pressure is preferably 0.02 MPa to 10 MPa, and more preferably 0.05 MPa to 5 MPa.

According to the semiconductor device production method of the present embodiment, a semiconductor device can be obtained in which the chip 320 on which a through electrode is formed is mounted to the mounting substrate 322 and the space between the chip 320 and the mounting substrate 322 is sealed with the sheet-shaped composition 316. According to the semiconductor device production method of the present embodiment, the adhesive 318 is applied to the portion where the sheet-shaped resin composition 316 is exposed. Therefore, when the temporary fixing layer 313 is dissolved by the solvent to peel the support 312 from the wafer 311, it is difficult for the solvent to make contact with the sheet-shaped resin composition 316. As a result, dissolution of the sheet-shaped resin composition 316 can be suppressed. As described above, the dissolution of the sheet-shaped resin composition 316 is suppressed, and therefore the sheet-shaped resin composition 316 of the chip 320 with the sheet-shaped resin composition 316 that is obtained in the step F3 sufficiently functions as a sheet-shaped resin composition for sealing the space between the chip 320 and the mounting substrate 322. Because the dissolution of the sheet-shaped resin composition 316 is suppressed, the yield ratio of the semiconductor device that is obtained in the step G3 (a semiconductor device in which the space between the chip and the mounting substrate is sealed with the sheet-shaped composition) can be improved.

In this embodiment, a case is explained in which the adhesive 318 is not peeled off. However, the third part of the present invention is not limited by this example, and the adhesive may be peeled off after the step E3 (the support peeling step) (for example, after the step E3 and before the dicing step). The case in which the adhesive is peeled off after the step E3 (the support peeling step) is superior in suppression of contamination of the semiconductor element by the adhesive as compared with the case in which the adhesive is not peeled off. The adhesive may be peeled physically with a cutting blade, etc. or may be dissolved by using a solvent for dissolving an adhesive that can dissolve the adhesive.

### EXAMPLES

Below, preferred examples of the present invention (the first part to the third part of the present invention) are explained in detail. The materials, the compounding amounts, etc., that are described in the examples are not for limiting the key points of this invention to these examples as long as there is no specific limiting description. “Parts” in these examples mean “parts by weight.”

### First Part of the Present Invention

Each example, etc., described below corresponds to the first part of the present invention.

### Example 1

### Production of the Sheet-Shaped Resin Composition

The following materials (a) to (g) were dissolved in methylethylketone to obtain a solution of resin composition having a solid concentration of 23.6% by weight.
(a) Acrylic ester polymer (trade name “Paracron W-197CM” manufactured by Negami Chemical Industrial Co., Ltd.) having ethylacrylate-methylmethacrylate as a main component: 100 parts
(b) Epoxy resin 1 (trade name “Epikote 1004” manufactured by Japan Epoxy Resins Co., Ltd.): 56 parts
(c) Epoxy resin 2 (trade name “Epikote 828” manufactured by Japan Epoxy Resins Co., Ltd.): 19 parts
(d) Phenol resin (trade name “Milex XLC-4L” manufactured by Mitsui Chemicals, Inc.): 75 parts
(e) Spherical silica (trade name “SO-25R” manufactured by Admatechs Company Limited): 167 parts
(f) Organic acid (trade name “Ortho-Anisic Acid” manufactured by Tokyo Chemical Industry Co., Ltd.): 1.3 parts
(g) Imidazole catalyst (trade name “2PHZ-PW” manufactured by Shikoku Chemicals Corporation): 1.3 parts

The solution of resin composition was applied on a release-treated film consisting of a silicone release-treated polyethyleneterephthalate film (a release liner) having thickness 50 μm, and dried at 130° C. for 2 minutes to produce a circular sheet-shaped resin composition A having thickness 20 μm and diameter 190 mm.

<Production of the Dicing Tape>

First, an experimental apparatus for polymerization was prepared having a 1 liter round-bottom separable flask, a separable cover, a liquid separating funnel, a thermometer, a nitrogen introducing tube, a Liebig condenser, a vacuum seal, a stirrer, and a stirring blade.

Next, 50 parts of 2-methoxyethylacrylate (trade name: Acrycs C-1 manufactured by Toagosei Co., Ltd.), 35 parts of acryloylmorpholine (trade name: ACMO manufactured by Kohjin Co., Ltd.), 15 parts of 2-hydroxyethylacrylate (trade name: Acrycs βHEA manufactured by Toagosei Co., Ltd.), and 0.2% by weight (that is, 0.2 part) to the total amount of monomer (100 parts) of 2,2′-azobis-isobutyronitrile (Kishida Chemical Co., Ltd.) as a thermal polymerization initiator were added to ethylacetate as a solvent in the experimental apparatus for polymerization so that the total amount of monomer became 20% by weight of the solution. After that, the mixture was stirred at a normal temperature (23° C.) for 1 hour while performing nitrogen substitution.

Then, the mixture was stirred for 10 hours while controlling the temperature of the solution in the experimental apparatus for polymerization to 60° C.±2° C. by using a water bath under nitrogen flow to obtain an intermediate polymer solution. In the middle of polymerization of the intermediate polymer, ethylacetate was appropriately dripped to control the temperature during polymerization and to prevent a rapid increase of the viscosity (for example, an increase of the viscosity caused by hydrogen bonding originated from a polar group of the monomer side chain, etc.).

Next, the solution of the intermediate polymer was cooled to room temperature (23° C.). After that, 16 parts by weight of 2-isocyanateethylmethacrylate (“Karenz MOI” manufactured by Showa Denko K.K.) and 0.1 part by weight of dibutyltin (IV) dilaurate (manufactured by Wako Pure Chemical Industries, Ltd.) were added.

Then, the mixture was stirred for 24 hours while maintaining the temperature to 50° C. under an air atmosphere to obtain a final polymer solution.

30 parts by weight of dipentaerythritolhexaacrylate (“KAYARAD DPHA” manufactured by Nippon Kayaku Co., Ltd.), 3 parts by weight of 1-hydroxycyclohexylphenylketone (“Irgacure 184” manufactured by Ciba Specialty Chemicals) as a photopolymerization initiator, and 3 parts by weight of a polyisocyanate cross-linking agent (“Coronate L” manufactured by Nippon Polyurethane Industry Co., Ltd.) to 100 parts by weight of the solid content in the final polymer solution were mixed in the final polymer solution, and the resulting mixture was uniformly stirred to obtain a pressure-sensitive adhesive solution.

The obtained pressure-sensitive adhesive solution was applied to the release-treated surface of the silicone release-treated PET film using an applicator, and dried for 2 minutes in a dryer at 120° C. to obtain a pressure-sensitive adhesive layer A having thickness 30 μm.

Next, a film of a straight-chain low-density polyethylene resin (trade name: Novatec LD manufactured by Japan Polyethylene Corporation) was produced by T-die extrusion. The thickness of the straight-chain low-density polyethylene resin layer was 100 μm. Then, a corona treatment was performed on one side of the straight-chain low-density polyethylene resin layer and the pressure-sensitive adhesive layer A was pasted to the corona treated side using a hand roller. After that, they were adhered together by placing at 50° C. for 72 hours to obtain a dicing tape A according to the present example.

<Production of the Dicing Tape-Integrated Sheet-Shaped Resin Composition>

The sheet-shaped resin composition A was pasted on the pressure-sensitive adhesive layer A of the dicing tape A using a hand roller to produce a dicing tape-integrated sheet-shaped resin composition A.

<Production of the Temporary Fixing Layer>

In an atmosphere under nitrogen flow, 29.5 g of polyetherdiamine (“D-4000” manufactured by Huntsman, molecular weight: 4023.5), 90.3 g of 4,4′-diaminophenylether (DDE, molecular weight: 200.2), and 100.0 g of pyromellitic dianhydride (PMDA, molecular weight: 218.1) were mixed in 2528.0 g of N,N-dimethylacetamide (DMAc) and reacted at 70° C. to obtain a polyamic acid solution A. The polyamic acid solution A was cooled to room temperature (23° C.). The polyamic acid solution A was applied on a separator, and dried at 90° C. for 3 minutes to obtain a temporary fixing layer A having thickness 100 μm.

<Adjustment of the Adhesive Solution>

A solution B for an adhesive layer (a polyamic acid solution B) was obtained with the same method of producing the solution for the temporary fixing layer A (the polyamic acid solution A) except the compounding according Table 1 was used. The obtained solution for the adhesive layer was cooled to room temperature (23° C.)

TABLE 1

| | Temporary | Temporary |
|---|---|---|
| | Fixing Layer | Fixing Layer |
| | A | B |
| DMAc (g) | 2528 | 2206 |
| D-4000 (g) | 29.5 | 0 |
| DDE (g) | 90.3 | 91.8 |
| PMDA (g) | 100 | 100 |

[Process Evaluation]

The temporary fixing layer A was pasted to a silicon wafer having diameter 195 mm and thickness 725 μm. Pasting was performed at temperature 90° C. and pressure 0.1 MPa by roll lamination. After pasting, the temporary fixing layer A was imidized at 300° C. for 1.5 hours under a nitrogen atmosphere.

A pedestal (a silicon wafer having diameter 200 mm and thickness 726 μm) was pasted as a support to the side of the temporary fixing layer A where the silicon wafer was not pasted previously. At this time, pasting was performed at temperature 120° C. and pressure 0.3 MPa.

Next, the solution B for the adhesive layer was applied between the temporary fixing layer A and the bevel part of the pedestal, and dried to form an adhesive layer B. The temporary fixing layer A was thereby fixed to the pedestal.

A laminate was thereby obtained in which the pedestal, the temporary fixing layer A, and the silicon wafer were laminated one by one.

Back grinding was performed using the obtained laminate so that the thickness of the wafer became 50 μm. Then, the obtained grinded laminate was laminated to the dicing tape-integrated sheet-shaped resin composition A in a condition of 80° C., 0.2 MPa, and 10 mm/s. At this time, a wafer fixing jig was laminated to the dicing tape-integrated sheet-shaped resin composition A at the same time. Lamination was performed so that the adhesive layer B did not protrude from the wafer.

Then, the laminate with the dicing tape-integrated sheet-shaped resin composition A was soaked in the NMP solution for 30 seconds up to the pressure-sensitive adhesive layer A with the pedestal down, and was taken out. The pedestal was peeled off using tweezers, and the obtained silicon wafer with the dicing tape-integrated sheet-shaped resin composition A was observed from the base (the straight-chain low-density polyethylene resin layer) side of the dicing tape-integrated sheet-shaped resin composition A. The case in which the NMP solution penetrated into the adhesive layer B was marked as X, and the case in which the NMP solution was not penetrated was marked as O. The result is shown in Table 2.

### Comparative Example 1

The process evaluation was performed in the same way as Example 1 except the diameter of the sheet-shaped resin composition was changed to 230 mm. Because the diameter of the silicon wafer was 195 mm, the sheet-shaped resin composition protruded from the silicon wafer in a plane view in Comparative Example 1. The result is shown in Table 2.

TABLE 2

| | | Comparative |
|---|---|---|
| | Example 1 | Example 1 |
| Diameter of Sheet-Shaped | 190 mm | 230 mm |
| Resin Composition | | |
| Process Evaluation | ○ | x |

### Second Part of the Present Invention

Each example, etc., described below corresponds to the second part of the present invention.

### Example 2

### Production of the Sheet-Shaped Resin Composition

The following materials (a) to (g) were dissolved in methylethylketone to obtain a solution of resin composition having a solid concentration of 23.6% by weight.
(a) Acrylic ester polymer (trade name “Paracron W-197CM” manufactured by Negami Chemical Industrial Co., Ltd.) having ethylacrylate-methylmethacrylate as a main component: 100 parts
(b) Epoxy resin 1 (trade name “Epikote 1004” manufactured by Japan Epoxy Resins Co., Ltd.): 56 parts
(c) Epoxy resin 2 (trade name “Epikote 828” manufactured by Japan Epoxy Resins Co., Ltd.): 19 parts
(d) Phenol resin (trade name “Milex XLC-4L” manufactured by Mitsui Chemicals, Inc.): 75 parts
(e) Spherical silica (trade name “SO-25R” manufactured by Admatechs Company Limited): 167 parts
(f) Organic acid (trade name “Ortho-Anisic Acid” manufactured by Tokyo Chemical Industry Co., Ltd.): 1.3 parts
(g) Imidazole catalyst (trade name “2PHZ-PW” manufactured by Shikoku Chemicals Corporation): 1.3 parts

The solution of resin composition was applied on a release-treated film consisting of a silicone release-treated polyethyleneterephthalate film (a release liner) having thickness 50 μm, and dried at 130° C. for 2 minutes to produce a circular sheet-shaped resin composition A2 having thickness 20 μm and diameter 190 mm.

<Production of the Dicing Tape>

First, an experimental apparatus for polymerization was prepared having a 1 liter round-bottom separable flask, a separable cover, a liquid separating funnel, a thermometer, a nitrogen introducing tube, a Liebig condenser, a vacuum seal, a stirrer, and a stirring blade.

Next, 50 parts of 2-methoxyethylacrylate (trade name: Acrycs C-1 manufactured by Toagosei Co., Ltd.), 35 parts of acryloylmorpholine (trade name: ACMO manufactured by Kohjin Co., Ltd.), 15 parts of 2-hydroxyethylacrylate (trade name: Acrycs βHEA manufactured by Toagosei Co., Ltd.), and 0.2% by weight (that is, 0.2 part) to the total amount of monomer (100 parts) of 2,2′-azobis-isobutyronitrile (Kishida Chemical Co., Ltd.) as a thermal polymerization initiator were added to ethylacetate as a solvent in the experimental apparatus for polymerization so that the total amount of monomer became 20% by weight of the solution. After that, the mixture was stirred at a normal temperature (23° C.) for 1 hour while performing nitrogen substitution.

Then, the mixture was stirred for 10 hours while controlling the temperature of the solution in the experimental apparatus for polymerization to 60° C.±2° C. by using a water bath under nitrogen flow to obtain an intermediate polymer solution. In the middle of polymerization of the intermediate polymer, ethylacetate was appropriately dripped to control the temperature during polymerization and to prevent a rapid increase of the viscosity (for example, an increase of the viscosity caused by hydrogen bonding originated from a polar group of the monomer side chain, etc.).

Next, the solution of the intermediate polymer was cooled to room temperature (23° C.). After that, 16 parts by weight of 2-isocyanateethylmethacrylate (“Karenz MOI” manufactured by Showa Denko K.K.) and 0.1 part by weight of dibutyltin (IV) dilaurate (manufactured by Wako Pure Chemical Industries, Ltd.) were added.

Then, the mixture was stirred for 24 hours while maintaining the temperature to 50° C. under an air atmosphere to obtain a final polymer solution.

30 parts by weight of dipentaerythritolhexaacrylate (“KAYARAD DPHA” manufactured by Nippon Kayaku Co., Ltd.), 3 parts by weight of 1-hydroxycyclohexylphenylketone (“Irgacure 184” manufactured by Ciba Specialty Chemicals) as a photopolymerization initiator, and 3 parts by weight of a polyisocyanate cross-linking agent (“Coronate L” manufactured by Nippon Polyurethane Industry Co., Ltd.) to 100 parts by weight of the solid content in the final polymer solution were mixed in the final polymer solution, and the resulting mixture was uniformly stirred to obtain a pressure-sensitive adhesive solution.

The obtained pressure-sensitive adhesive solution was applied to the release-treated surface of the silicone release-treated PET film using an applicator, and dried for 2 minutes in a dryer at 120° C. to obtain a pressure-sensitive adhesive layer A2 having thickness 30 μm.

Next, a film of a straight-chain low-density polyethylene resin (trade name: Novatec LD manufactured by Japan Polyethylene Corporation) was produced by T-die extrusion. The thickness of the straight-chain low-density polyethylene resin layer was 100 μm. Then, a corona treatment was performed on one side of the straight-chain low-density polyethylene resin layer and the pressure-sensitive adhesive layer A2 was pasted to the corona treated side using a hand roller. After that, they were adhered together by placing at 50° C. for 72 hours to obtain a dicing tape A2 according to the present example.

<Production of the Barrier Layer>

The pressure-sensitive adhesive solution that is the same as the one used in the production of the pressure-sensitive adhesive layer A2 was applied to the release-treated surface of the silicone release-treated PET film using an applicator, and dried for 2 minutes in a dryer at 120° C. to obtain a pressure-sensitive adhesive layer having thickness 30 μm. Then, the pressure-sensitive adhesive layer was processed into a donut shape having outer diameter (outside diameter) 240 mm and inner diameter (inside diameter) 190 mm to obtain a barrier layer A2.

<Production of the Dicing Tape-Integrated Sheet-Shaped Resin Composition>

The sheet-shaped resin composition A2 was pasted on the pressure-sensitive adhesive layer A2 of the dicing tape A2 using a hand roller, and the barrier layer A2 was pasted to the region outside of the sheet-shaped resin composition A2 using a hand roller. Pasting was performed at room temperature (23° C.). A dicing tape-integrated sheet-shaped resin composition A2 was thereby produced.

<Production of the Temporary Fixing Layer>

In an atmosphere under nitrogen flow, 29.5 g of polyetherdiamine (“D-4000” manufactured by Huntsman, molecular weight: 4023.5), 90.3 g of 4,4′-diaminophenylether (DDE, molecular weight: 200.2), and 100.0 g of pyromellitic dianhydride (PMDA, molecular weight: 218.1) were mixed in 2528.0 g of N,N-dimethylacetamide (DMAc) and reacted at 70° C. to obtain a polyamic acid solution A2. The polyamic acid solution A2 was cooled to room temperature (23° C.). The polyamic acid solution A2 was applied on a separator, and dried at 90° C. for 3 minutes to obtain a temporary fixing layer A2 having thickness 100 μm.

<Adjustment of the Adhesive Solution>

A solution B2 for an adhesive layer (a polyamic acid solution B2) was obtained with the same method of producing the solution for the temporary fixing layer A2 (the polyamic acid solution A2) except the compounding according Table 3 was used. The obtained solution for the adhesive layer was cooled to room temperature (23° C.)

TABLE 3

| | Temporary | Temporary |
|---|---|---|
| | Fixing Layer | Fixing Layer |
| | A2 | B2 |
| DMAc (g) | 2528 | 2206 |
| D-4000 (g) | 29.5 | 0 |
| DDE (g) | 90.3 | 91.8 |
| PMDA (g) | 100 | 100 |

[Process Evaluation]

The temporary fixing layer A2 was pasted to a silicon wafer having diameter 195 mm and thickness 725 μm. Pasting was performed at temperature 90° C. and pressure 0.1 MPa by roll lamination. After pasting, the temporary fixing layer A2 was imidized at 300° C. for 1.5 hours under a nitrogen atmosphere.

A pedestal (a silicon wafer having diameter 200 mm and thickness 726 μm) was pasted as a support to the side of the temporary fixing layer A2 where the silicon wafer was not pasted previously. At this time, pasting was performed at temperature 120° C. and pressure 0.3 MPa.

Next, the solution B2 for the adhesive layer was applied between the temporary fixing layer A2 and the bevel part of the pedestal, and dried to form an adhesive layer B. The temporary fixing layer A2 was thereby fixed to the pedestal.

A laminate was thereby obtained in which the pedestal, the temporary fixing layer A2, and the silicon wafer were laminated one by one.

Back grinding was performed using the obtained laminate so that the thickness of the wafer became 50 μm. Then, the obtained grinded laminate was laminated to the dicing tape-integrated sheet-shaped resin composition A2 in a condition of 80° C., 0.2 MPa, and 10 mm/s. At this time, a wafer fixing jig was laminated to the dicing tape-integrated sheet-shaped resin composition A2 at the same time. Lamination was performed so that the adhesive layer B did not protrude from the wafer.

Then, the laminate with the dicing tape-integrated sheet-shaped resin composition A2 was soaked in the NMP solution for 30 seconds up to the pressure-sensitive adhesive layer A2 with the pedestal down, and was taken out. The pedestal was peeled off using tweezers, and the obtained silicon wafer with the dicing tape-integrated sheet-shaped resin composition A2 was observed from the base (the straight-chain low-density polyethylene resin layer) side of the dicing tape-integrated sheet-shaped resin composition A2. The case in which the NMP solution penetrated into the adhesive layer B was marked as X, and the case in which the NMP solution was not penetrated was marked as O. The result is shown in Table 4.

### Comparative Example 2

The process evaluation was performed in the same way as Example 2 except the diameter of the sheet-shaped resin composition was changed to 230 mm and the barrier layer was not provided. Because the diameter of the silicon wafer is 195 mm, the sheet-shaped resin composition protruded from the silicon wafer in a plane view in Comparative Example 2. The result is shown in Table 4.

TABLE 4

| | | Comparative |
|---|---|---|
| | Example 2 | Example 2 |
| Diameter of Sheet-Shaped | 190 mm | 230 mm |
| Resin Composition | | |
| Process Evaluation | ○ | x |

### Third Part of the Present Invention

Each of the example, etc. described below corresponds to the third part of the present invention.

### Example 3

### Production of the Sheet-Shaped Resin Composition

The following materials (a) to (g) were dissolved in methylethylketone to obtain a solution of resin composition having a solid concentration of 23.6% by weight.
(a) Acrylic ester polymer (trade name “Paracron W-197CM” manufactured by Negami Chemical Industrial Co., Ltd.) having ethylacrylate-methylmethacrylate as a main component: 100 parts
(b) Epoxy resin 1 (trade name “Epikote 1004” manufactured by Japan Epoxy Resins Co., Ltd.): 56 parts
(c) Epoxy resin 2 (trade name “Epikote 828” manufactured by Japan Epoxy Resins Co., Ltd.): 19 parts
(d) Phenol resin (trade name “Milex XLC-4L” manufactured by Mitsui Chemicals, Inc.): 75 parts
(e) Spherical silica (trade name “SO-25R” manufactured by Admatechs Company Limited): 167 parts
(f) Organic acid (trade name “Ortho-Anisic Acid” manufactured by Tokyo Chemical Industry Co., Ltd.): 1.3 parts
(g) Imidazole catalyst (trade name “2PHZ-PW” manufactured by Shikoku Chemicals Corporation): 1.3 parts

The solution of resin composition was applied on a release-treated film consisting of a silicone release-treated polyethyleneterephthalate film (a release liner) having thickness 50 μm, and dried at 130° C. for 2 minutes to produce a circular sheet-shaped resin composition A3 having thickness 20 μm and diameter 230 mm.

<Production of the Dicing Tape>

First, an experimental apparatus for polymerization was prepared having a 1 liter round-bottom separable flask, a separable cover, a liquid separating funnel, a thermometer, a nitrogen introducing tube, a Liebig condenser, a vacuum seal, a stirrer, and a stirring blade.

Next, 50 parts of 2-methoxyethylacrylate (trade name: Acrycs C-1 manufactured by Toagosei Co., Ltd.), 35 parts of acryloylmorpholine (trade name: ACMO manufactured by Kohjin Co., Ltd.), 15 parts of 2-hydroxyethylacrylate (trade name: Acrycs βHEA manufactured by Toagosei Co., Ltd.), and 0.2% by weight (that is, 0.2 part) to the total amount of monomer (100 parts) of 2,2′-azobis-isobutyronitrile (Kishida Chemical Co., Ltd.) as a thermal polymerization initiator were added to ethylacetate as a solvent in the experimental apparatus for polymerization so that the total amount of monomer became 20% by weight of the solution. After that, the mixture was stirred at a normal temperature (23° C.) for 1 hour while performing nitrogen substitution.

Then, the mixture was stirred for 10 hours while controlling the temperature of the solution in the experimental apparatus for polymerization to 60° C.±2° C. by using a water bath under nitrogen flow to obtain an intermediate polymer solution. In the middle of polymerization of the intermediate polymer, ethylacetate was appropriately dripped to control the temperature during polymerization and to prevent a rapid increase of the viscosity (for example, an increase of the viscosity caused by hydrogen bonding originated from a polar group of the monomer side chain, etc.).

Next, the solution of the intermediate polymer was cooled to room temperature (23° C.). After that, 16 parts by weight of 2-isocyanateethylmethacrylate (“Karenz MOI” manufactured by Showa Denko K.K.) and 0.1 part by weight of dibutyltin (IV) dilaurate (manufactured by Wako Pure Chemical Industries, Ltd.) were added.

Then, the mixture was stirred for 24 hours while maintaining the temperature to 50° C. under an air atmosphere to obtain a final polymer solution.

30 parts by weight of dipentaerythritolhexaacrylate (“KAYARAD DPHA” manufactured by Nippon Kayaku Co., Ltd.), 3 parts by weight of 1-hydroxycyclohexylphenylketone (“Irgacure 184” manufactured by Ciba Specialty Chemicals) as a photopolymerization initiator, and 3 parts by weight of a polyisocyanate cross-linking agent (“Coronate L” manufactured by Nippon Polyurethane Industry Co., Ltd.) to 100 parts by weight of the solid content in the final polymer solution were mixed in the final polymer solution, and the resulting mixture was uniformly stirred to obtain a pressure-sensitive adhesive solution.

The obtained pressure-sensitive adhesive solution was applied to the release-treated surface of the silicone release-treated PET film using an applicator, and dried for 2 minutes in a dryer at 120° C. to obtain a pressure-sensitive adhesive layer A3 having thickness 30 μm.

Next, a film of a straight-chain low-density polyethylene resin (trade name: Novatec LD manufactured by Japan Polyethylene Corporation) was produced by T-die extrusion. The thickness of the straight-chain low-density polyethylene resin layer was 100 μm. Then, a corona treatment was performed on one side of the straight-chain low-density polyethylene resin layer and the pressure-sensitive adhesive layer A3 was pasted to the corona treated side using a hand roller. After that, they were adhered together by placing at 50° C. for 72 hours to obtain a dicing tape A33 according to the present example.

<Production of the Dicing Tape-Integrated Sheet-Shaped Resin Composition>

The sheet-shaped resin composition A3 was pasted on the pressure-sensitive adhesive layer A3 of the dicing tape A3 using a hand roller to produce a dicing tape-integrated sheet-shaped resin composition A3.

<Production of the Temporary Fixing Layer>

In an atmosphere under nitrogen flow, 29.5 g of polyetherdiamine (“D-4000” manufactured by Huntsman, molecular weight: 4023.5), 90.3 g of 4,4′-diaminophenylether (DDE, molecular weight: 200.2), and 100.0 g of pyromellitic dianhydride (PMDA, molecular weight: 218.1) were mixed in 2528.0 g of N,N-dimethylacetamide (DMAc) and reacted at 70° C. to obtain a polyamic acid solution A3. The polyamic acid solution A3 was cooled to room temperature (23° C.). The polyamic acid solution A3 was applied on a separator, and dried at 90° C. for 3 minutes to obtain a temporary fixing layer A3 having thickness 100 μm.

<Adjustment of the Adhesive Solution>

A solution B3 for an adhesive layer (a polyamic acid solution B3) was obtained with the same method of producing the solution for the temporary fixing layer A3 (the polyamic acid solution A3), except the compounding according Table 5 was used. The obtained solution for the adhesive layer was cooled to room temperature (23° C.)

TABLE 5

| | Temporary | Temporary |
|---|---|---|
| | Fixing Layer | Fixing Layer |
| | A3 | B3 |
| DMAc (g) | 2528 | 2206 |
| D-4000 (g) | 29.5 | 0 |
| DDE (g) | 90.3 | 91.8 |
| PMDA (g) | 100 | 100 |

[Process Evaluation]

The temporary fixing layer A3 was pasted to a silicon wafer having diameter 195 mm and thickness 725 μm. Pasting was performed at temperature 90° C. and pressure 0.1 MPa by roll lamination. After pasting, the temporary fixing layer A3 was imidized at 300° C. for 1.5 hours under a nitrogen atmosphere.

A pedestal (a silicon wafer having diameter 200 mm and thickness 726 μm) was pasted as a support to the side of the temporary fixing layer A3 where the silicon wafer was not pasted previously. At this time, pasting was performed at temperature 120° C. and pressure 0.3 MPa.

Next, the solution B3 for the adhesive layer was applied between the temporary fixing layer A3 and the bevel part of the pedestal, and dried to form an adhesive layer B. The temporary fixing layer A3 was thereby fixed to the pedestal.

A laminate was thus obtained in which the pedestal, the temporary fixing layer A3, and the silicon wafer were laminated one by one.

Back grinding was performed using the obtained laminate so that the thickness of the wafer became 50 μm. Then, the obtained grinded laminate was laminated to the dicing tape-integrated sheet-shaped resin composition A3 in a condition of 80° C., 0.2 MPa, and 10 mm/s. At this time, a wafer fixing jig was laminated to the dicing tape-integrated sheet-shaped resin composition A3 at the same time.

Next, the pressure-sensitive adhesive solution (the adhesive) that was the same as the one used in the production of the pressure-sensitive adhesive layer A3 was applied to the portion where the sheet-shaped resin composition A3 was exposed, and dried at 100° C. for 3 minutes.

Then, the laminate with the dicing tape-integrated sheet-shaped resin composition A3 was soaked in the NMP solution for 30 seconds up to the pressure-sensitive adhesive layer A3 with the pedestal down, and was taken out. The pedestal was peeled off using tweezers, and the obtained silicon wafer with the dicing tape-integrated sheet-shaped resin composition A3 was observed from the base (the straight-chain low-density polyethylene resin layer) side of the dicing tape-integrated sheet-shaped resin composition A3. The case in which the NMP solution penetrated into the adhesive layer B was marked as X, and the case in which the NMP solution was not penetrated was marked as O. The result is shown in Table 6.

### Comparative Example 3

The process evaluation was performed in the same way as Example 3 except the pressure-sensitive adhesive solution (the adhesive) that is the same as the one used in the production of the pressure-sensitive adhesive layer A3 was not applied to the portion where the sheet-shaped resin composition A3 was exposed. Because the diameter of the silicon wafer is 230 mm, the sheet-shaped resin composition protruded from the silicon wafer in a plane view in Comparative Example 3. The result is shown in Table 6.

TABLE 6

| | | Comparative |
|---|---|---|
| | Example 3 | Example 3 |
| Process Evaluation | ○ | x |

1. A semiconductor device production method, comprising:
a step A of preparing a wafer with a support including a wafer, a temporary fixing layer, and a support bonded to one side of the wafer, on which a through electrode is formed, with the temporary fixing layer interposed therebetween,
a step B of preparing a dicing tape-integrated sheet-shaped resin composition including a dicing tape and a sheet-shaped resin composition smaller in an outer shape than the other side of the wafer formed on the dicing tape,
a step C of pasting the other side of the wafer with a support to the sheet-shaped resin composition of the dicing tape-integrated sheet-shaped resin composition, and
a step D of dissolving the temporary fixing layer with a solvent to peel the support from the wafer.

2. The semiconductor device production method according to claim 1, comprising a step E of dicing the wafer together with the sheet-shaped resin composition after the step D to obtain a chip with the sheet-shaped resin composition.

3. The semiconductor device production method according to claim 2, comprising a step F of arranging the chip with the sheet-shaped resin composition on a mounting substrate after the step E, and sealing a space between the chip and the mounting substrate with the sheet-shaped composition while bonding the electrode of the chip to the electrode of the mounting substrate.

4. The semiconductor device production method according to claim 1, wherein the step C is performed under reduced pressure.

5. A sheet-shaped resin composition that is used in the semiconductor device production method according to claim 1.

6. A dicing tape-integrated sheet-shaped resin composition that is used in the semiconductor device production method according to claim 1.
